(19) United States
(12) Patent Application Publication
(10) Pub. No.: US 2026/0052716 A1
(43) Pub. Date: Feb. 19, 2026

(54) LATERAL ETCHING OF DIELECTRIC LAYERS IN A GATE-ALL-AROUND DEVICE

(71) Applicant: Taiwan Semiconductor Manufacturing Company, Ltd., Hsin-Chu (TW)

(72) Inventors: Kuan-Ting Lee, Hsinchu City (TW); Hua-Yun Lee, Kaohsiung City (TW)

(21) Appl. No.: 18/807,023

(22) Filed: Aug. 16, 2024

(51) Int. Cl. H01L 29/66; H01L 21/311; H01L 29/423; H01L 29/775; H01L 29/786

(52) U.S. Cl. CPC H10D 30/014; H01L 21/31116; H10D 30/43; H10D 30/6735; H10D 30/6757; H10D 64/018

(57) ABSTRACT

A stack of first semiconductor layers and second semiconductor layers is formed. The first semiconductor layers each have a first material composition. The second semiconductor layers each have a second material composition different from the first material composition. The first semiconductor layers interleave with the second semiconductor layers in the stack. The second semiconductor layers are replaced with a plurality of dielectric layers. An etching process is performed to the dielectric layers. The etching is performed at a process pressure between about 600 milli-Torrs and about 800 milli-Torrs or at a process temperature between about 16 degrees Celsius and about 20 degrees Celsius.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

Recently, multigate devices have been introduced to improve gate control. Multigate devices have been observed to increase gate-channel coupling, reduce OFF-state current, and/or reduce short-channel effects (SCEs). One such multigate device is the gate-all around (GAA) device, which includes a gate structure that can extend, partially or fully, around a channel region to provide access to the channel region on at least two sides. GAA devices enable aggressive scaling down of IC technologies, maintaining gate control and mitigating SCEs, while seamlessly integrating with conventional IC manufacturing processes. As GAA devices continue to scale, challenges have arisen. For example, it may be more difficult to configure a lateral dimension of metal gate structures in GAA devices, especially as device sizes are scaled down. As a result, device performance may be degraded. Therefore, although existing IC structures and fabrication techniques have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flowchart of a method for fabricating a semiconductor structure according to various aspects of the present disclosure.

FIG. 2 is a top view of a semiconductor structure according to some embodiments of the present disclosure.

FIGS. 3, 4A-9A, 10, and 11A-12A are cross-sectional side views of a semiconductor structure along the line A-A′ in FIG. 2, at various fabrication stages, according to some embodiments of the present disclosure.

FIGS. 4B-9B and 11B-12B are enlarged views of a portion of the semiconductor structure in FIGS. 4A-9A and 11A-12A, respectively, according to some embodiments of the present disclosure.

FIG. 11C is a cross-sectional side view of the semiconductor structure in FIG. 11A and along the line B-B′ as in FIG. 2, according to some embodiments of the present disclosure.

FIG. 13 is a block diagram of a tool used to perform an etching process according to some embodiments of the present disclosure.

FIGS. 14A and 14B are cross-sectional side views of a portion of a semiconductor structure according to some embodiments of the present disclosure.

FIG. 15 is a graph associated with an etching process according to some embodiments of the present disclosure.

FIGS. 16 and 17A-17C are cross-sectional side views of portions of a semiconductor structure according to some embodiments of the present disclosure.

FIG. 18A is a cross-sectional side view of a portion of a semiconductor structure according to some embodiments of the present disclosure.

FIG. 18B is a planar top view of a portion of a semiconductor structure according to some embodiments of the present disclosure.

FIG. 19 is a circuit diagram of a memory cell according to some embodiments of the present disclosure.

FIG. 20 is a block diagram of a semiconductor fabrication facility according to some embodiments of the present disclosure.

### DETAILED DESCRIPTION

The following disclosure provides many different embodiments, or examples, for implementing different features. Reference numerals and/or letters may be repeated in the various examples described herein. This repetition is for the purpose of simplicity and clarity and does not in itself dictate a relationship between the various disclosed embodiments and/or configurations. Further, specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Moreover, the formation of a feature on, connected to, and/or coupled to another feature in the present disclosure may include embodiments in which the features are formed in direct contact, and may also include embodiments in which additional features may be formed interposing the features, such that the features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

Multi-gate devices (e.g. gate-all-around (GAA) devices) have been introduced in an effort to improve gate control by increasing gate-channel coupling, reduce OFF-state current, and reduce short-channel effects (SCEs). GAA devices can be aggressively scaled down while maintaining gate control and mitigating SCEs. However, GAA devices may still face certain fabrication challenges. For example, it may be difficult to flexibly configure the critical dimension (CD) of the metal gate structures of GAA devices. Frequently, the GAA devices may include a stack of metal gate structure segments, where the top metal gate structure segment has the smallest dimension, and the bottom metal gate structure segment has the largest dimension. Such a profile may be a result of issues associated with etching processes performed to laterally etch dummy oxide layers, such that the etched dummy oxide layers have such a profile (e.g., the top dummy oxide layer being the shortest, and the bottom dummy oxide layer being the longest). The metal gate structures are formed later to replace the dummy oxide layers and therefore inherit the profiles of the dummy oxide layers. The present disclosure pertains to methods performed as a part of the GAA fabrication to address these issues discussed above, such that the resulting metal gate structures can achieve a better profile, as discussed below in more detail.

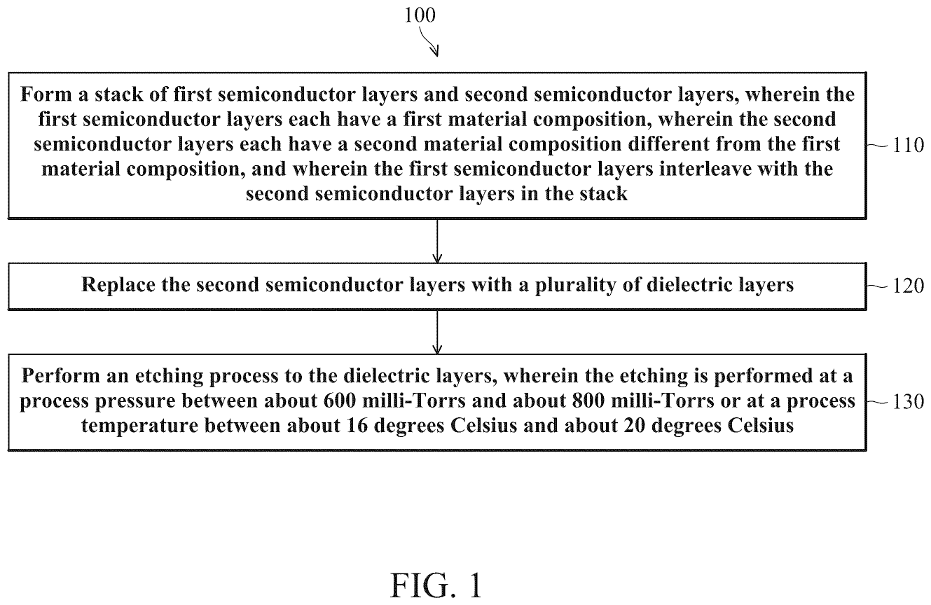

Referring now to FIG. 1, a flow chart of an example method 100 for fabricating an embodiment of a semiconductor device is illustrated. In some embodiments, the semiconductor device is a GAA device where its gate structure, or portions thereof, are formed around all-sides of a channel region (e.g. surrounding a portion of a channel region). In some instances, a GAA device may also be referred to as a quad-gate device where the channel region has four sides and the gate structure is formed on all four sides. The channel region of a GAA device may include one or more semiconductor layers, each of which may be in one of many different shapes, such as wire (or nanowire), sheet (or nanosheet), bar (or nano-bar), and/or other suitable shapes. In embodiments, the channel region of a GAA device may have multiple horizontal semiconductor layers (such as nanowires, nanosheets, or nano-bars) (hereinafter collectively referred to as “nanochannels”) vertically spaced, making the GAA device a stacked horizontal GAA device. The GAA devices presented herein may be a complementary metal-oxide-semiconductor (CMOS) GAA device, a p-type metal-oxide-semiconductor (pMOS) GAA device, or an n-type metal-oxide-semiconductor (nMOS) GAA device. Further, the GAA devices may have one or more channel regions associated with a single, contiguous gate structure, or multiple gate structures. One of ordinary skill may recognize other examples of semiconductor devices that may benefit from aspects of the present disclosure. For example, other types of metal-oxide semiconductor field effect transistors (MOSFETs), such as planar MOSFETs, FinFETs, other multi-gate FETs may benefit from the present disclosure. The GAA devices and methods of manufacture that are proposed in the present disclosure exhibit desirable properties, examples being: reduced doping diffusion, reduced built-in stress, reduced device degradation, improved silicon performance, higher current drive, reduced short-channel effects (SCEs), and decreased capacitance between adjacent conductive regions, such as between a source/drain region and adjacent SiGe residue.

The method 100 includes a step 110, in which a stack of first semiconductor layers and second semiconductor layers is formed. The first semiconductor layers each have a first material composition. The second semiconductor layers each have a second material composition different from the first material composition. The first semiconductor layers interleave with the second semiconductor layers in the stack.

The method 100 includes a step 120, in which the second semiconductor layers are replaced with a plurality of dielectric layers.

The method 100 includes a step 130, in which an etching process is performed to the dielectric layers. The etching is performed at a process pressure between about 600 milli-Torrs and about 800 milli-Torrs or at a process temperature between about 16 degrees Celsius and about 20 degrees Celsius.

In some embodiments, the etching process is performed through a plurality of cycles. Each of the cycles comprises an etching step performed at an etching chamber and a baking step performed at a baking chamber. In some embodiments, the etching chamber and the baking chamber are integrated into a same/single tool. In some embodiments, the baking step is performed at a baking temperature in a range between about 120 degrees Celsius and about 130 degrees Celsius. In some embodiments, the etching step generates a byproduct from the dielectric layers, and the baking step transforms the byproduct into a gaseous chemical that is removable from the baking chamber. In some embodiments, the etching step is performed at least in part using an etchant that contains HF or NH₃, and the byproduct contains (NH4)₂SiF6(s).

In some embodiments, the etching process laterally etches the dielectric layers without substantially etching the first semiconductor layers.

It is understood that the method 100 may include steps that are performed before, during, and/or after the steps 110-130. For example, the method 100 may include a step of replacing the dielectric layers with gate structures (e.g., gate structures that include a high-k gate dielectric and a metal gate electrode). For reasons of simplicity, these steps are not specifically discussed in detail herein.

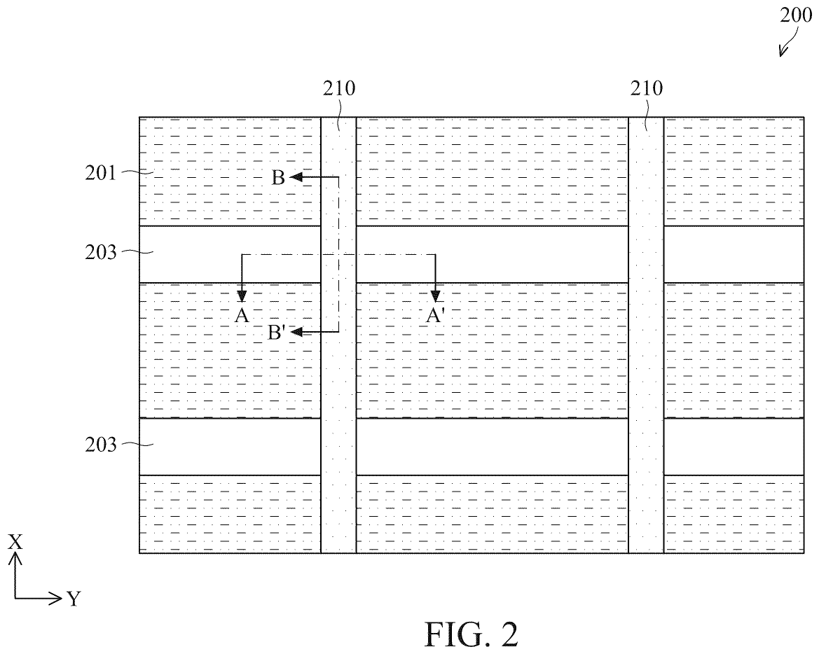

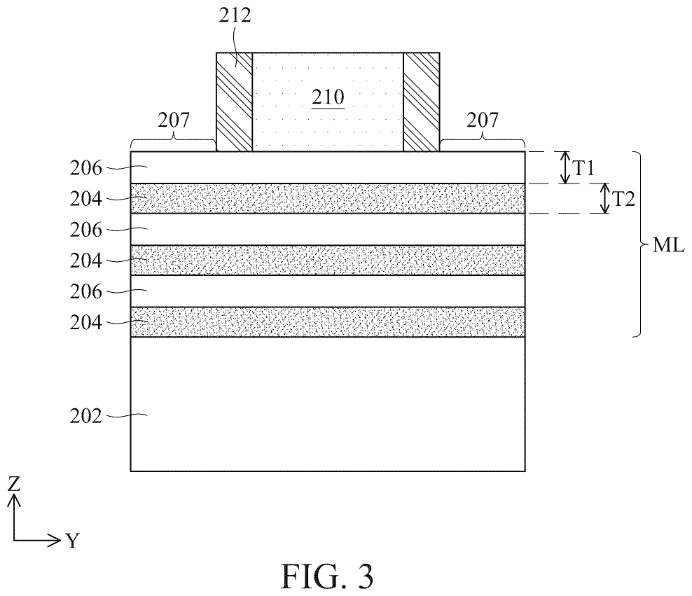

Referring to FIGS. 2 and 3, a semiconductor structure 200 fabricated according to the various aspects of the present disclosure includes semiconductor substrate 202 and a plurality of fins 203 protruding from the semiconductor substrate 202. The fins 203 and separated by isolation features 201 and one or more dummy gate stacks 210 disposed over the fins 203.

In some embodiments, the semiconductor substrate 202 includes a semiconductor material, such as bulk silicon (Si). Alternatively, or additionally, another elementary semiconductor, such as germanium (Ge) in a crystalline structure, may also be included in the semiconductor substrate 202. The semiconductor substrate 202 may also include a compound semiconductor, such as silicon germanium (SiGe), silicon carbide (SiC), gallium arsenic (GaAs), gallium phosphide (GaP), indium phosphide (InP), indium arsenide (InAs), and/or indium antimonide (InSb), or combinations thereof. The semiconductor substrate 202 may also include a semiconductor-on-insulator substrate, such as Si-on-insulator (SOI), SiGe-on-insulator (SGOI), Ge-on-insulator (GOI) substrates.

Portions of the semiconductor substrate 202 may be doped and referred to as doped portions. The doped portions may be doped with p-type dopants, such as boron (B) or boron fluoride (BF3), or doped with n-type dopants, such as phosphorus (P) or arsenic (As). The doped portions may also be doped with combinations of p-type and n-type dopants (e.g. to form a p-type well and an adjacent n-type well). The doped portions may be formed directly on the semiconductor substrate 202, in a p-well structure, in an n-well structure, in a dual-well structure, or using a raised structure.

In some embodiments, semiconductor layers 204 and 206 (collectively referred to as a “multi-layer stack” or “ML”) are formed over the semiconductor substrate 202 in an interleaving or alternating fashion, extending vertically (e.g. along the Z-direction in FIG. 3) from the semiconductor substrate 202. For example, a semiconductor layer 204 is disposed over the semiconductor substrate 202, a semiconductor layer 206 is disposed over the semiconductor layer 204, another semiconductor layer 204 is disposed over the semiconductor layer 206, so on and so forth. In the depicted embodiments, there are three layers of semiconductor layers 206 and three layers of semiconductor layers 204 alternating between each other. However, there may be any appropriate number of layers in the ML. For example, there may be 2 to 10 layers of semiconductor layers 206, alternating with 2 to 10 layers of semiconductor layers 204 in the ML. The material compositions of the semiconductor layers 206 and the semiconductor layers 204 are configured such that they have an etching selectivity in a subsequent etching process. For example, in some embodiments, the semiconductor layers 204 contain silicon germanium (SiGe), while the semiconductor layers 206 contain silicon (Si). In some other embodiments, the semiconductor layers 206 contain SiGe, while the semiconductor layers 204 contain Si. In the depicted embodiment, each of the semiconductor layers 206 has a substantially same thickness (e.g., less than 5% difference between two semiconductor layers 206), depicted in FIG. 3 as thickness T1, while each of the semiconductor layers 204 has a substantially same thickness (e.g., less than 5% difference between two semiconductor layers 204), depicted in FIG. 3 as thickness T2. T1 and T2 are about 2 nanometers (nm) to about 12 nm.

The stack of semiconductor layers 204 and 206 are then patterned into a plurality of fin structures, for example, into the fins 203 as in FIG. 2. Each of the fins 203 includes a stack of the semiconductor layers 204 and 206 disposed in an alternating manner with respect to one another. The fins 203 each extends lengthwise (e.g. longitudinally) in a horizontal direction (e.g. in the Y-direction) and are separated from each other (e.g. laterally) in a different horizontal direction (e.g. in the X-direction), as shown in FIG. 2. It is understood that the X-direction and the Y-direction are perpendicular to each other, and that the Z-direction is a vertical direction that is orthogonal (or normal) to a plane defined by the X-direction and the Y-direction. The semiconductor substrate 202 may have its top surface aligned in parallel to the X-Y plane.

The fins 203 may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins. The patterning may utilize multiple etching processes which may include a dry etching and/or wet etching. The regions in which the fins are formed will be used to form active devices through subsequent processing and are thus referred to as active regions. For example, each of the fins 203 is formed in an active region. Both of the fins 203 in FIG. 2 protrude out of the semiconductor substrate 202 (e.g., the doped portions).

The semiconductor structure 200 includes isolation features 201, which may include shallow trench isolation (STI) features in some embodiments. The isolation features 201 are formed on the semiconductor substrate 202 and surround the active regions. In some examples, formation of the isolation features 201 includes etching trenches into the semiconductor substrate 202 between the active regions and filling the trenches with one or more dielectric materials such as silicon oxide, silicon nitride, silicon oxynitride, other suitable materials, or combinations thereof. Any appropriate methods, such as a chemical vapor deposition (CVD) process, an atomic layer deposition (ALD) process, a physical vapor deposition (PVD) process, a plasma-enhanced CVD (PECVD) process, a plasma-enhanced ALD (PEALD) process, and/or combinations thereof may be used for depositing the isolation features 201. The isolation features 201 may have a multi-layer structure such as a thermal oxide liner layer over the semiconductor substrate 202 and a filling layer (e.g., silicon nitride or silicon oxide) over the thermal oxide liner layer. Alternatively, the isolation features 201 may be formed using any other isolation formation techniques. Although not depicted, in some embodiments, the fins 203 are located above a top surface of the isolation features 201 (e.g. protrude out of the isolation features 201) and are also located above a top surface of the semiconductor substrate 202.

Referring to FIGS. 2 and 3, the dummy gate stacks 210 are formed over a portion of each of the fins 203, and over the isolation features 201, in between the fins 203. The dummy gate stacks 210 may be configured to extend lengthwise (e.g. longitudinally) in parallel to each other, for example, each along the X-direction, as shown in FIG. 2. In some embodiments, each dummy gate stack 210 wraps around the top surface and side surfaces of each of the fins 203. The dummy gate stack 210 may include polysilicon. In some embodiments, the dummy gate stack 210 also includes one or more mask layers, which are used to pattern the dummy gate electrode layers. The dummy gate stack 210 may undergo a gate replacement process through subsequent processing to form metal gates, such as a high-k metal gate, as discussed in greater detail below. The dummy gate stack 210 may also undergo a second gate replacement process to form a dielectric based gate that electrically isolates the semiconductor structure 200 from neighboring devices. The dummy gate stack 210 may be formed by a procedure including deposition, lithography patterning, and etching processes. The deposition processes may include CVD, ALD, PVD, other suitable methods, and/or combinations thereof.

Referring to FIG. 3, gate spacers 212 are formed on sidewalls of the dummy gate stack 210. The gate spacers 212 include one or more dielectric materials and may include silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, porous oxide, or combinations thereof. The gate spacers 212 may include a single layer or a multi-layer structure. In some embodiments, each of the gate spacers 212 may have a thickness (e.g. measured in the Y-direction) in a range from about 3 nm to about 10 nm. A thickness within the stated range of values may be needed for device performance, especially for advanced technology nodes. In some embodiments, the gate spacers 212 may be formed by depositing a spacer layer (containing the dielectric material) over the dummy gate stack 210, followed by an anisotropic etching process to remove portions of the spacer layer from the top surfaces of the dummy gate stack 210. After the etching process, portions of the spacer layer on the sidewall surfaces of the dummy gate stack 210 substantially remain and become the gate spacers 212. In some embodiments, the anisotropic etching process is a dry (e.g. plasma) etching process. Additionally, or alternatively, the formation of the gate spacers 212 may also involve chemical oxidation, thermal oxidation, ALD, CVD, and/or other suitable methods. In the active regions, the gate spacers 212 are formed over the top layer of the semiconductor layers 204 and 206. Accordingly, the gate spacers 212 may also be interchangeably referred to as top spacers 212. In some examples, one or more material layers (not shown) may also be formed between the dummy gate stack 210 and the corresponding gate spacers 212. The one or more material layers may include an interfacial layer and/or a high-k dielectric layer (e.g., having a dielectric constant greater than a dielectric constant of silicon oxide, which is about 3.9), as examples.

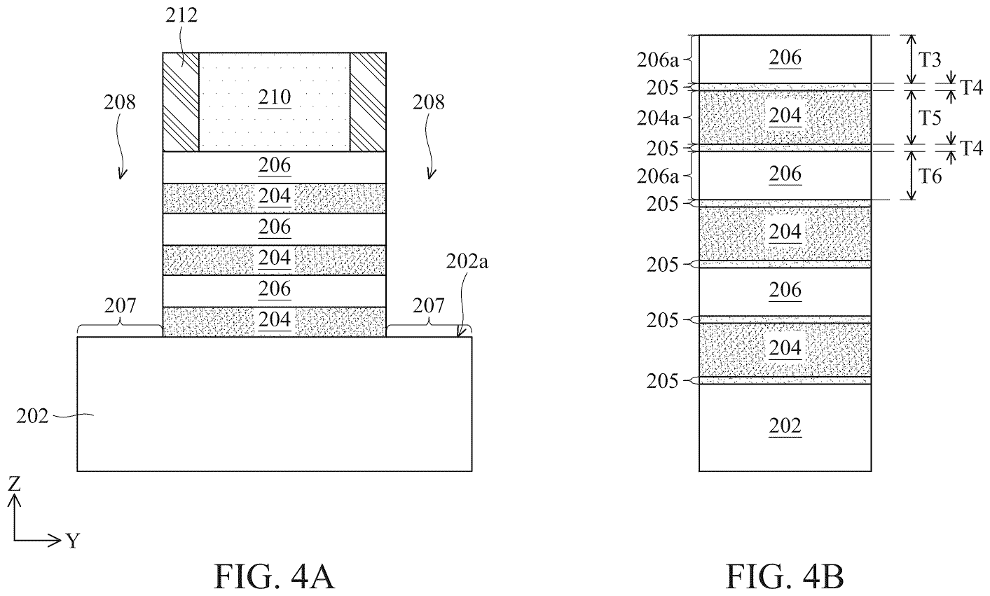

Referring to FIG. 4A, exposed portions of the fins 203 (i.e., source/drain regions 207 of the fins 203 that are not covered by the dummy gate stack 210) are at least partially removed to form source/drain recesses (trenches) 208. Source/drain region(s) may refer to a source or a drain, individually or collectively, depending upon the context. In the depicted embodiment, an etching process completely removes the ML in the source/drain regions 207 of the fins 203, thereby exposing substrate portions of the fins 203 in the source/drain regions 207. The source/drain recesses 208 thus have sidewalls defined by remaining portions of the ML, which are disposed under the dummy gate stack 210, and bottoms defined by the semiconductor substrate 202.

A top surface 202a of the semiconductor substrate 202 is exposed to the source/drain recesses 208. In some embodiments, the etching process removes some, but not all, of the ML, such that the source/drain recesses 208 have bottoms defined by the semiconductor layer 204 or the semiconductor layer 206 in the source/drain regions 207. In some embodiments, the etching process further removes some, but not all, of the substrate portions of the fins 203, such that the source/drain recesses 208 extend below a topmost surface of the semiconductor substrate 202. In other words, the top surface 202a is below a topmost surface of the semiconductor substrate 202. The etching process can include a dry etching process, a wet etching process, other suitable etching process, or combinations thereof. In some embodiments, the etching process is a multi-step etch process. For example, the etching process may alternate etchants to separately and alternately remove the semiconductor layers 204 and the semiconductor layers 206. In some embodiments, parameters of the etching process are configured to selectively etch the ML with minimal (to no) etching of the dummy gate stack 210 and the gate spacers 212 and/or the isolation features 201. In some embodiments, a lithography process, such as those described herein, is performed to form a patterned mask layer that covers the dummy gate stack 210 and the gate spacers 212 and/or the isolation features 201, and the etching process uses the patterned mask layer as an etch mask.

FIG. 4B is an enlarged view of a portion (in the dotted rectangle) of the semiconductor structure 200 in FIG. 4A. In some embodiments, the semiconductor structure 200 further includes intermix layers 205 (also referred to as “transmission layers 205”) having a mixture of materials of the semiconductor layers 204 and the semiconductor layers 206. In some embodiments, the intermix layers 205 are formed from epitaxial growing of the semiconductor layers 204 and 206. The ML can include the intermix layers 205 and core layers 206a and 204a. The core layers 206a and 204a include relatively high concentrations (e.g., greater than 90%) of materials of the semiconductor layers 204 and 206 (e.g., Si or SiGe), respectively. Each of the semiconductor layers 206 can include a core layer 206a and at least a portion of an intermix layer 205. Each of the semiconductor layers 204 can include a core layer 204a and at least a portion of an intermix layer 205.

In some embodiments, the core layer 206a is adjacent to and above the intermix layer 205. In such an intermix layer 205, a concentration of the material of the core layer 206a (e.g., Si) gradually decreases from about 90% to about 10% from top to bottom along the Z-direction, while a concentration of the material of the core layer 204a (e.g., SiGe) gradually increases from about 10% to about 90% from top to bottom along the Z-direction. In such embodiments, an atomic percentage of Ge in the intermix layer 205 gradually increases from about 0.005% to about 20% from top to bottom along the Z-direction. In some other embodiments, the core layer 204a is adjacent to and above the intermix layer 205. In such an intermix layer 205, a concentration of the material of the core layer 206a (e.g., Si) gradually increases from about 10% to about 90% from top to bottom along the Z-direction, while a concentration of the material of the core layer 204a (e.g., SiGe) gradually decreases from about 90% to about 10% from top to bottom along the Z-direction. In such embodiments, an atomic percentage of Ge in intermix layers 205 gradually decreases from about 20% to about 0.005% from top to bottom along the Z-direction. In some embodiments, the bottommost intermix layer 205 has a concentration of the material of the semiconductor substrate 202 (e.g., Si) gradually increases from about 10% to about 90% from top to bottom along the Z-direction, while a concentration of the material of the core layer 204a (e.g., SiGe) gradually decreases from about 90% to about 10% from top to bottom along the Z-direction.

In the depicted embodiment, the core layer 206a interfacing only one layer of the intermix layers 205 has a thickness T3 ranging from about 2 nm to about 12 nm, the core layer 206a interfacing two layers of the intermix layers 205 has a thickness T6 ranging from about 2 nm to about 12 nm, the core layer 204a interfacing two layers of the intermix layers 205 has a thickness T5 ranging from about 2 nm to about 12 nm, and each of the intermix layers 205 has a substantially same thickness (e.g., less than 5% difference) T4 ranging from about 0.1 nm to about 2 nm. T5 can be equal to T6. In some embodiments, T5 is different from T6.

In some embodiments, each of the semiconductor layers 204 and 206 and the intermix layers 205 have uniform profiles on each X-Y plane. For example, on an X-Y plane across one layer of the intermix layers 205, a concentration of the material of the core layer 204a (e.g., SiGe) is substantially the same. Therefore, an interface between the intermix layer 205 and the adjacent core layer 204a or 206a extends along an X-Y plane, and thicknesses of each core layers 206a or 204a are substantially the same at different locations on an X-Y plane. For example, a thickness of a core layer 206a or 204a close to a sidewall of the core layer 206a or 204a is substantially the same (e.g., less than 5% difference) as a thickness of the core layer 206a or 204a at center (the portion directly under dummy gate stack 210). Similarly, thicknesses of each intermix layers 205 are substantially the same at different locations on an X-Y plane. For example, a thickness of an intermix layer 205 close to a sidewall of the intermix layer 205 is substantially the same (e.g., less than 5% difference) as a thickness of the intermix layer 205 at center (the portion directly under dummy gate stack 210).

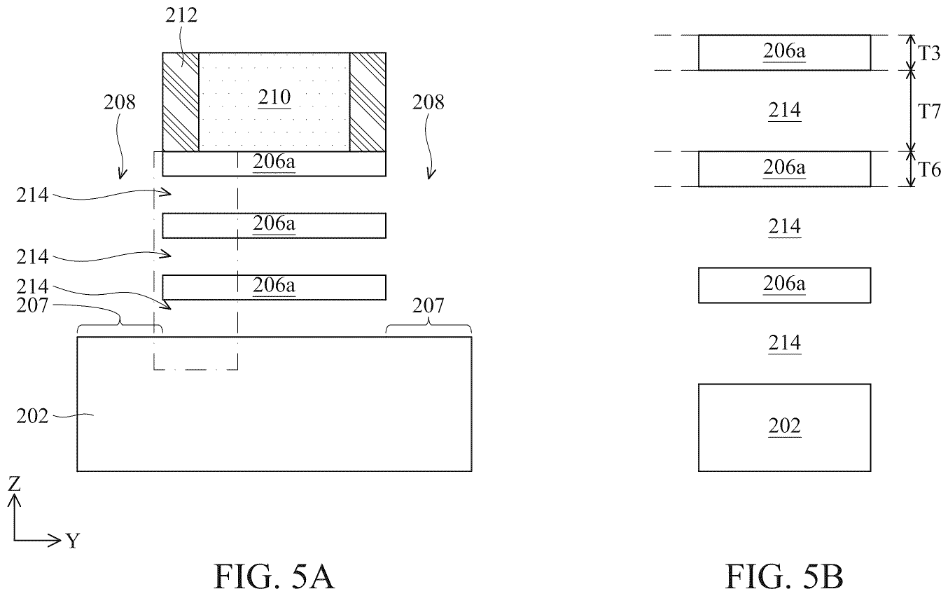

Referring to FIG. 5A, the semiconductor layers 204 (exposed by the source/drain recesses 208) are selectively removed from the ML, thereby forming suspended semiconductor layers 206 and openings 214 in between the vertically (e.g. in the Z-direction) adjacent semiconductor layers 206 (or the semiconductor substrate 202, where applicable). Particularly, the openings 214 are through openings that are overlapped with the core layers 204a and the intermix layers 2O5, and are spanning between a pair of the source/drain regions 207. FIG. 5B is an enlarged view of a portion (in the dotted rectangle) of the semiconductor structure 200 in FIG. 5A.

In the depicted embodiment, an etching process selectively etches the core layers 204a and the intermix layers 205 with minimal (to no) etching of the core layers 206a and, in some embodiments, minimal (to no) etching of the gate spacers 212. In embodiments, the core layers 206a remain unetched. In some embodiments, the semiconductor layers 204 are completely removed. In the depicted embodiment, the core layers 204a and the intermix layers 205 are completely removed, thus remaining semiconductor layers 206 only include the core layers 206a. In some other embodiments, the core layers 204a are completely removed, while the intermix layers 205 are partially removed, thus the core layers 206a and the remaining portion of the intermix layers 205 collectively form the remaining semiconductor layers 206. For ease of description, regardless of whether the intermix layers 205 are completely removed, the remaining semiconductor layers 206 hereinafter are referred to as core layers 206a.

Various etching parameters can be tuned to achieve selective etching of the core layers 204a and the intermix layers 2O5, such as etchant composition, etching temperature, etching solution concentration, etching time, etching pressure, source power, Radio-Frequency (RF) bias voltage, RF bias power, etchant flow rate, other suitable etching parameters, or combinations thereof. For example, an etchant is selected for the etching process that etches the material of the core layers 204a (in the depicted embodiment, silicon germanium) at a higher rate than the material of the core layers 206a (in the depicted embodiment, silicon) (i.e., the etchant has a high etch selectivity with respect to the material of the core layers 204a). The intermix layers 205 include certain concentrations of the material of the core layers 204a and thus can be selectively removed with the core layers 204a.

The etching process may include a dry etching process, a wet etching process, other suitable etching process, or combinations thereof. In some embodiments, a dry etching process (such as an RIE process) utilizes a fluorine-containing gas (for example, SF₆) to selectively etch the core layers 204a and the intermix layers 205. In some embodiments, a ratio of the fluorine-containing gas to an oxygen-containing gas (for example, O₂), an etching temperature, and/or an RF power may be tuned to selectively etch silicon germanium or silicon. In some embodiments, a wet etching process utilizes an etching solution that includes ammonium hydroxide (NH₄OH) and water (H₂O) to selectively etch the core layers 204a and the intermix layers 205. In some embodiments, a chemical vapor phase etching process using hydrochloric acid (HCl) selectively etches the core layers 204a and the intermix layers 205.

In the depicted embodiment, the ML includes three suspended core layers 206a vertically stacked that will provide three channels through which current will flow between respective epitaxial source/drain features during operation of the semiconductor structure 200. The core layers 206a are thus referred to as channel layers 206a hereinafter. The channel layers 206a are separated from each other by the openings 214. The channel layers 206a are also separated from the semiconductor substrate 202 by one of the openings 214. A spacing T7 is defined between channel layers 206a along the z-direction. The spacing T7 corresponds to a dimension of the openings 214 along the Z-direction. In the depicted embodiment, the core layers 204a and the intermix layers 205 are completely removed, thus the spacing T7 is equal to (T5+2*T4), which is a sum of thicknesses of one of the core layer 204a and two intermix layers 205. In some other embodiments, the core layers 204a are completely removed while the intermix layers 205 are partially removed, thus the spacing T7 is less than (T5+2*T4). The core layers 204a and the removed intermix layers 205 can be collectively referred to as non-channel layers. In some embodiments, spacings of each openings 214 are substantially the same at different locations on an X-Y plane. For example, the spacing of an opening 214 close to an edge (e.g., a portion directly under the gate spacer 212) is substantially the same (e.g., less than 5% difference) as spacing of the opening 214 at center (e.g., a portion directly under dummy gate stack 210).

In some embodiments, the spacing T7 is within a range between about 2 nm and about 14 nm. In some embodiments, each channel layer 206a has nanometer-sized dimensions and can be referred to as a “nanowire,” which generally refers to a channel layer suspended in a manner that will allow a metal gate to physically contact at least two sides of the channel layer, and in GAA transistors, will allow the metal gate to physically contact at least four sides of the channel layer (i.e., surround the channel layer). In such embodiments, a vertical stack of suspended channel layers can be referred to as a nanostructure, and the process depicted in FIGS. 5A and 5B can be referred to as a channel nanowire release process. In some embodiments, after removing the core layers 204a and the intermix layers 2O5, an etching process is performed to modify a profile of the channel layers 206a to achieve desired dimensions and/or desired shapes (e.g., cylindrical-shaped (e.g., nanowire), rectangular-shaped (e.g., nanobar), sheet-shaped (e.g., nanosheet), etc.). The present disclosure further contemplates embodiments where the channel layers 206a (nanowires) have sub-nanometer dimensions depending on design requirements of semiconductor structure 200.

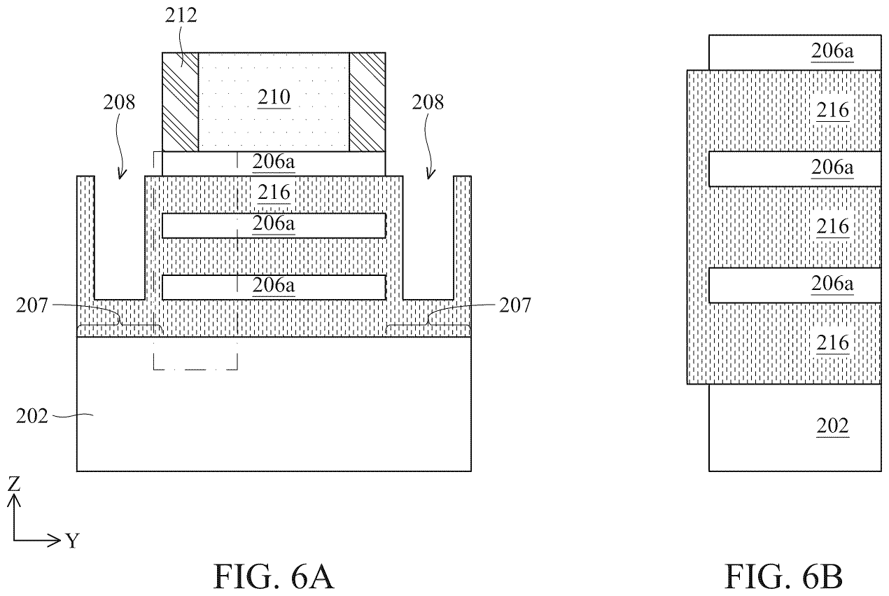

Referring to FIG. 6A, a dielectric material 216 is deposited into the opening 214 and conformally over the source/drain regions 207. FIG. 6B is an enlarged view of a portion (in the dotted rectangle) of the semiconductor structure 200 in FIG. 6A. The depositing the dielectric material can include any suitable methods, such as atomic layer deposition (ALD), plasma enhanced atomic layer deposition (PEALD), physical vapor deposition (PVD), or combinations thereof. In some embodiments, the depositing the dielectric material include an atomic layer deposition (ALD) process. The conformally depositing the dielectric material 216 can form a layer of the dielectric material 216 of a thickness of about 2 nm to about 14 nm. In some embodiments, the thickness is about 2 nm to about 7 nm. In some embodiments, the thickness is about 2 nm to about 5 nm.

The dielectric material 216 can include any suitable materials that have an etching selectively different from the channel layers 206a. In some embodiments, the dielectric material 216 include an oxide material. The dielectric material 216 can include at least one of silicon oxide (SiO₂, SiO), silicon oxynitride (SiON), aluminum oxide (Al₂O₃), silicon nitride, SiOC, SiOCN, and a combination thereof. In some embodiments, the dielectric material 216 includes a composition different from the semiconductor layers 204. In some embodiments, the dielectric material 216 includes less than 0.001% (atomic percentage) of germanium (Ge) or is free of Ge. In some embodiments, the dielectric material 216 is free of SiGe. If the Ge level in the dielectric material 216 is too high (e.g., greater than 1% atomic percentage), the following processes may be impacted by the Ge residue, which will be described in following descriptions.

In some embodiments, unlike the semiconductor layers 204 and 206, the channel layers 206a and the adjacent dielectric material 216 have clear boarders that are free of intermix sessions, which may include a mixture of materials of the channel layers 206a and the dielectric material 216. The channel layers 206a remain substantially unchanged (e.g., less than 5% changes) during the following processes, which will be described in further detail below.

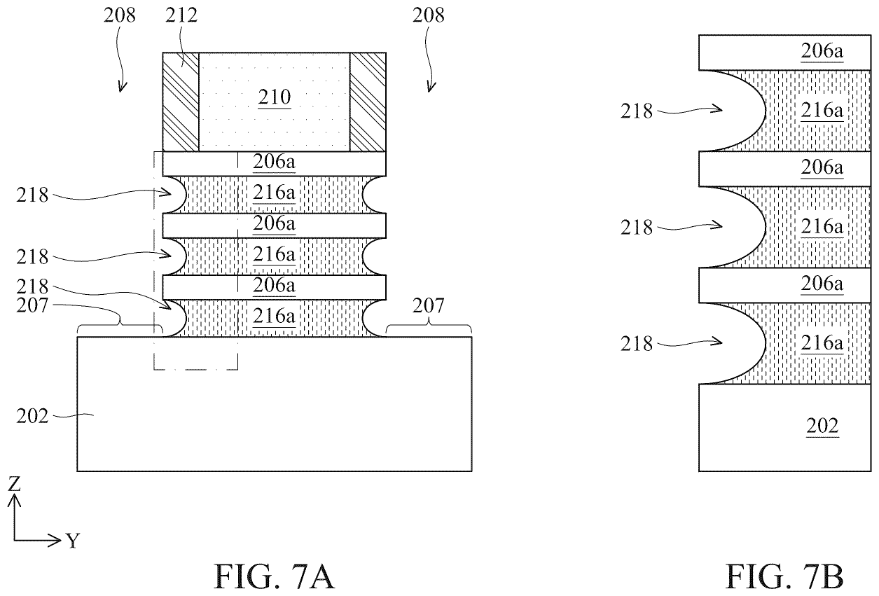

Referring to FIG. 7A, the dielectric material 216 in the source/drain regions 207 is removed, and portions of the dielectric material 216 between the adjacent channel layers 206a (or the semiconductor substrate 202, where applicable) are recessed through exposed sidewall surfaces in the source/drain regions 207 via a selective etching process to form undercuts 218 and dielectric layers 216a (or dielectric interposers 216a). FIG. 7B is an enlarged view of a portion (in the dotted rectangle) of the semiconductor structure 200 in FIG. 7A.

The selective etching process may be any suitable processes, such as a wet etching or a dry etching process. The extent to which the dielectric material 216 are recessed (or the size of the portion removed) is determined by the processing conditions such as the duration the dielectric material 216 is exposed to an etching chemical. In the depicted embodiments, the duration is controlled such that the dielectric material 216 in the source/drain regions 207 is completely removed, and side portions of the dielectric material 216 between adjacent channel layers 206a (or the semiconductor substrate 202, where applicable) are removed, while center portions (e.g., the dielectric layer 216a) of the dielectric material 216 between the adjacent channel layers 206a (or the semiconductor substrate 202, where applicable) remain substantially unchanged. As illustrated in FIG. 7B, the selective etching process creates the undercuts 218, which extend the source/drain recesses 208 into areas beneath the channel layers 206a and the gate spacers 212.

In some embodiments, the undercuts 218 have a convex shape as depicted in FIG. 7B. In some embodiments, the dielectric layers 216a include tip portions extending towards sidewalls of the channel layers 206a (or the semiconductor substrate 202, where applicable). In some embodiments, the tip portions extend to directly contact an entirety of a top or a bottom surface of a channel layer 206a (or the semiconductor substrate 202, where applicable). In such embodiments, the dielectric layers 216a have a sidewall coplanar with a sidewall of the channel layers 206a.

Meanwhile, the channel layers 206a are only slightly affected during the selective etching process. For example, prior to the selective etching process, side portions of the channel layers 206a each has a thickness T3 or T6 (see FIG. 5B). After the selective etching process, thicknesses of the side portions of the channel layers 206a may have about 1% to 5% change from T3 or T6. The etch selectivity between the channel layers 206a and the dielectric material 216 is made possible by the different material compositions between these layers. For example, the dielectric material 216 may be etched away at a substantially faster rate (e.g. more than about 5 times faster or about 10 times faster) than the channel layers 206a. Because spacings of each openings 214 as in FIGS. 5A-5B are substantially the same at different locations on an X-Y plane, and the channel layers 206a (or the semiconductor substrate 202, where applicable) remain substantially unchanged (e.g., less than 5% changes), spacing of each undercuts 218 along the Z-direction is substantially the same as a thickness of each of the dielectric layers 216a (e.g., less than 5% difference), which is about the same as T7.

As discussed above, the selective etching process may be a wet etching process in some embodiments. The etching technique and etchant(s) may be selected to etch the dielectric material 216 without significant etching of the surrounding structures, such as the channel layers 206a. In an embodiment, the channel layers 206a include Si and the dielectric material 216 include an oxide material (e.g., silicon oxide). In an embodiment, a hydrofluoric acid (HF) solution, such as a dilute hydrofluoric acid (DHF), may be used to selectively etch away the dielectric material 216. For example, the dielectric material 216 may be etched away at a substantially faster rate than the channel layers 206a (e.g., with a selectivity greater than 10). As a result, desired portions of the dielectric material 216 (e.g. the side portions of the dielectric material 216 between the adjacent channel layers 206a (or the semiconductor substrate 202, where applicable)) are removed, while the channel layers 206a remain substantially unchanged. The etching duration is adjusted such that the size of the removed portions of the dielectric material 216 are controlled. The optimal condition may be reached by additionally adjusting the etching temperature, dopant concentration, as well as other experimental parameters.

In some embodiments, the selective etching process may include a dry, plasma-free etching process performed using a suitable etch system, such as CERTAS® Gas Chemical Etch System, available from Tokyo Electron Limited, Tokyo, Japan. In some examples, the selective etching process may include etching using a standard clean 1 (SC-1) solution, a solution of ammonium hydroxide (NH₄OH), hydrogen peroxide (H₂O₂) and water (H₂O), hydrofluoric acid (HF), buffered HF, and/or a fluorine (F₂)-based etch. In some examples, the F₂-based etch may include an F₂ remote plasma etch.

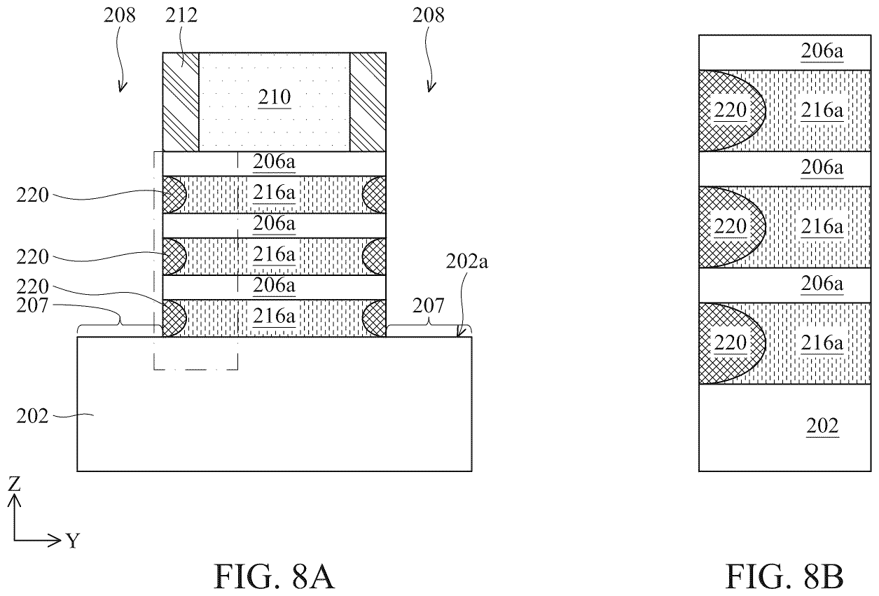

Referring to FIG. 8A, a second dielectric material is deposited into the undercuts 218. Deposition of the second dielectric material forms a spacer layer over the dummy gate stack 210, the gate spacers 212, and over features defining the source/drain recesses 208 (e.g., the channel layers 206a, the dielectric layers 216a, and the semiconductor substrate 202), and includes methods such as CVD, PVD, ALD, HDPCVD, MOCVD, RPCVD, PECVD, LPCVD, ALCVD, APCVD, plating, other suitable methods, or combinations thereof. The spacer layer partially (and, in some embodiments, completely) fills the source/drain recesses 208. The deposition process is configured to ensure that the spacer layer fills the undercuts 218. An etching process is then performed that selectively etches the spacer layer to form inner spacers 220 as depicted in FIGS. 8A-8B with minimal (to no) etching of the channel layers 206a, the dummy gate stack 210, and the gate spacers 212. In some embodiments, the spacer layer is removed from sidewalls of the gate spacers 212, sidewalls of the channel layers 206a, the dummy gate stack 210, and the semiconductor substrate 202. The spacer layer (and thus inner spacers 220) includes a material that is different than a material of the channel layers 206a and a material of the gate spacers 212 to achieve a desired etching selectivity during the etching process. In some embodiments, the spacer layer includes a material that is different than a material of the dielectric layers 216a. In some embodiments, the spacer layer includes a dielectric material that includes silicon, oxygen, carbon, nitrogen, other suitable material, or combinations thereof (for example, silicon oxide, silicon nitride, silicon oxynitride, silicon carbide, or silicon oxycarbonitride). In some embodiments, the spacer layer includes a low-k dielectric material, such as those described herein. In some embodiments, dopants (for example, p-type dopants, n-type dopants, or combinations thereof) are introduced into the dielectric material, such that the spacer layer includes a doped dielectric material.

FIG. 8B is an enlarged view of a portion (in the dotted rectangle) of the semiconductor structure 200 in FIG. 8A. In embodiments, the inner spacers 220 fill the undercuts 218 and thus have a convex shape as depicted in FIG. 8B. In such embodiments, the dielectric layers 216a include tip portions between the inner spacers 220 and the channel layers 206a (or semiconductor substrate 202, where applicable). In some embodiments, the tip portions extend towards a sidewall of the ML but are not exposed to the source/drain recesses 208. In such embodiments, the inner spacers 220 separate the dielectric layers 216a from the source/drain recesses 208. In some other embodiments, although not depicted, the tip portions extend to directly contact an entirety of a top and/or a bottom surface of the channel layers 206a (or the semiconductor substrate 202, where applicable). In such embodiments, the dielectric layers 216a are exposed to the source/drain recesses 208 and separate the adjacent inner spacer 220 from the adjacent channel layers 206a (or the semiconductor substrate 202, where applicable). The dielectric layers 216a can have a sidewall coplanar with a sidewall of the channel layers 206a.

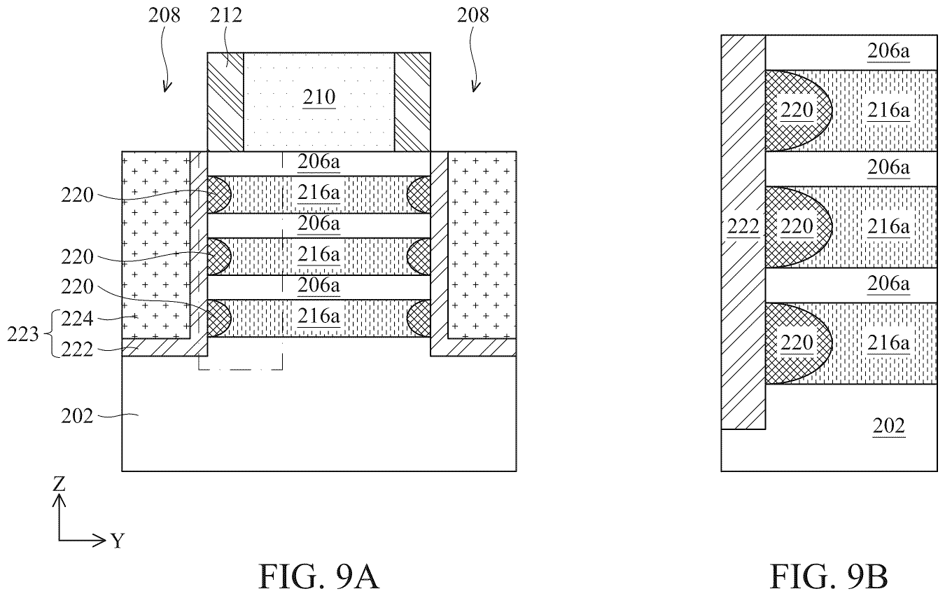

Referring to FIGS. 9A-9B, epitaxial source/drain features 223 are formed in the source/drain recesses 208. FIG. 9B is an enlarged view of a portion (in the dotted rectangle) of the semiconductor structure 200 in FIG. 9A. In some embodiments, one source/drain feature 223 is a source electrode, and the other source/drain feature 223 is a drain electrode. The channel layers 206a that extend from one source/drain feature 223 to the other source/drain feature 223 may form channels of the semiconductor structure 200. Multiple processes including etching and growth processes may be employed to grow the epitaxial source/drain features 223. Each of the epitaxial source/drain features 223 can include multiple layers, such as a first source/drain layer 222 and a second source/drain layer 224. In the depicted embodiment, the epitaxial source/drain features 223 have top surfaces that are substantially aligned with a top surface of the topmost channel layer 206a. However, in other embodiments, the epitaxial source/drain features 223 may alternatively have top surfaces that extend higher than the top surface of the topmost channel layer 206a (e.g. in the Z-direction). In the depicted embodiment, the epitaxial source/drain features 223 occupy a lower portion of the source/drain recesses 208 (e.g. the portion defined by the inner spacers 220 and the channel layers 206a), leaving an upper portion of the source/drain recesses 208 (e.g. the portion defined by the gate spacers 212) open. In some embodiments, the epitaxial source/drain features 223 may merge together, for example, along the X-direction, to provide a larger lateral width than an individual epitaxial feature.

The epitaxial source/drain features 223 may include any suitable semiconductor materials. For example, the epitaxial source/drain features 223 in an n-type GAA device may include Si, SiC, SiP, SiAs, SiPC, or combinations thereof; while the epitaxial source/drain features 223 in a p-type GAA device may include Si, SiGe, Ge, SiGeC, or combinations thereof. The epitaxial source/drain features 223 may be doped in-situ or ex-situ. For example, the epitaxially grown Si source/drain features may be doped with carbon to form silicon:carbon (Si:C) source/drain features, phosphorous to form silicon:phosphor (Si:P) source/drain features, or both carbon and phosphorous to form silicon carbon phosphor (SiCP) source/drain features; and the epitaxially grown SiGe source/drain features may be doped with boron. One or more annealing processes may be performed to activate the dopants in the epitaxial source/drain features 223. The annealing processes may include rapid thermal annealing (RTA) and/or laser annealing processes.

The epitaxial source/drain features 223 may directly interface with sidewalls of the inner spacers 220 and the channel layers 206a. During the epitaxial growth, semiconductor materials grow from the exposed top surface 202a of the semiconductor substrate 202 (e.g., the exposed top surface of doped region) as well as from the exposed side surfaces of the channel layers 206a. It is noted that semiconductor materials do not grow from the surfaces of the inner spacers 220 and the gate spacers 212 during the epitaxial growth process.

Because the semiconductor layers 204 and the intermix layers 205 have been removed, SiGe in the ML when forming the epitaxial source/drain features 223 is negligible (e.g., less than 0.0001% of the total SiGe in the semiconductor layers 204), doping diffusion to undesired regions is reduced, and built-in stress (e.g., tensile stress and compressive stress) during processes is reduced as well.

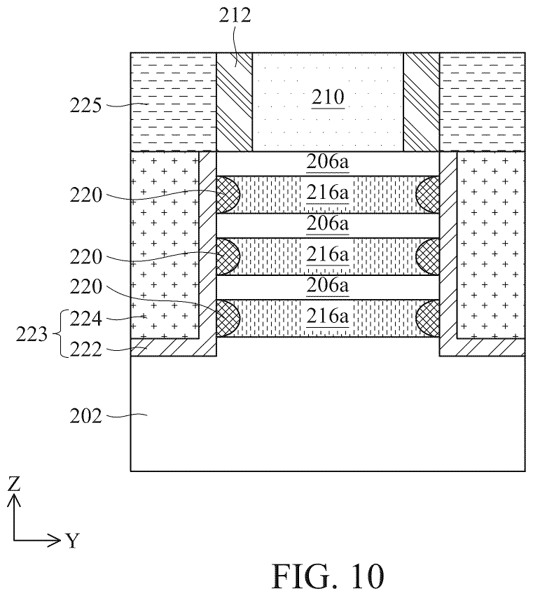

Referring to FIG. 10, an interlayer dielectric (ILD) layer 225 is formed over the epitaxial source/drain features 223 in the remaining spaces of the source/drain recesses 208, as well as vertically over the isolation features 201. The ILD layer 225 may also be formed in between the adjacent dummy gate stacks 210 along the Y-direction, and in between the source/drain features 223 along the X-direction. The ILD layer 225 may include a dielectric material, such as a high-k material, a low-k material, or an extreme low-k material. For example, the ILD layer 225 may include SiO₂, SiOC, SiON, or combinations thereof. The ILD layer 225 may include a single layer or multiple layers, and may be formed by a suitable technique, such as CVD, ALD, and/or spin-on techniques. In some embodiments, a contact etch-stop layer (CESL) is disposed between the ILD layer 225 and the isolation features 201, the epitaxial source/drain features 223 and the gate spacers 212. The CESL includes a material different than the ILD layer 225, such as a dielectric material that is different than the dielectric material of the ILD layer 225 to achieve the etch selectivity. For example, where the ILD layer 225 includes a low-k dielectric material, the CESL includes silicon and nitrogen, such as silicon nitride or silicon oxynitride. Subsequent to the deposition of the ILD layer 225 and/or the CESL, a CMP process and/or other planarization process can be performed to remove excessive portions of the ILD layer 225, thereby planarizing a top surface of the ILD layer 225, until reaching (exposing) a top portion (or top surface) of the dummy gate stack 210. Among other functions, the ILD layer 225 provides electrical isolation between the various components of the semiconductor structure 200.

The ILD layer 225 may be a portion of a multilayer interconnect (MLI) feature disposed over the semiconductor substrate 202. The MLI feature electrically couples various devices (for example, a GAA transistor of the semiconductor structure 200, transistors, resistors, capacitors, and/or inductors) and/or components (for example, gate structures and/or epitaxial source/drain features of GAA transistors), such that the various devices and/or components can operate as specified by design requirements of the semiconductor structure 200. The MLI feature includes a combination of dielectric layers and electrically conductive layers (e.g., metal layers) configured to form various interconnect structures. The conductive layers are configured to form vertical interconnect features, such as device-level contacts and/or vias, and/or horizontal interconnect features, such as conductive lines. Vertical interconnect features typically connect horizontal interconnect features in different layers (or different planes) of the MLI feature. During operation, the interconnect features are configured to route signals between the devices and/or the components of the semiconductor structure 200 and/or distribute signals (for example, clock signals, voltage signals, and/or ground signals) to the devices and/or the components of the semiconductor structure 200.

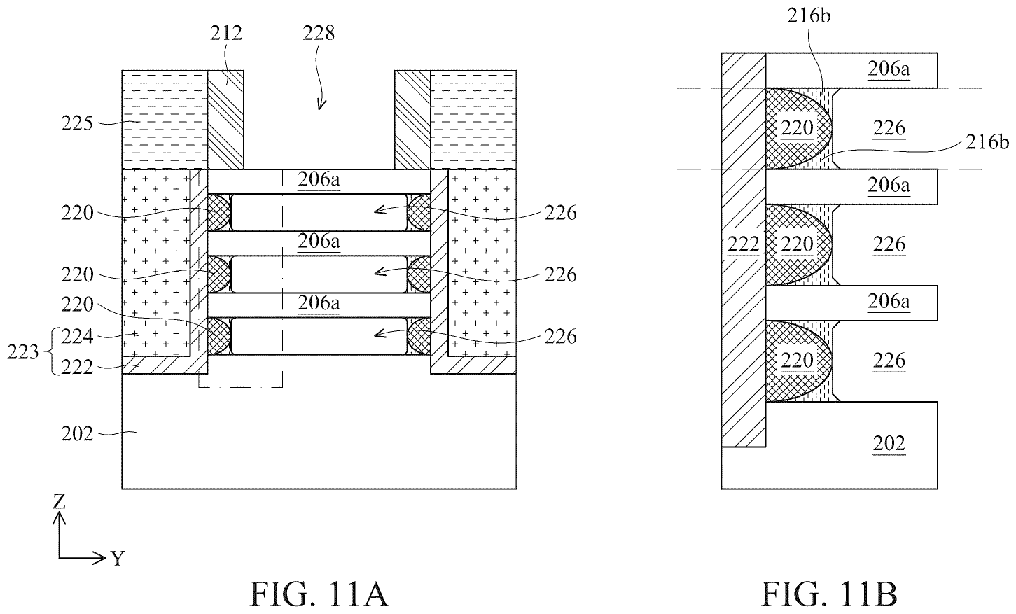

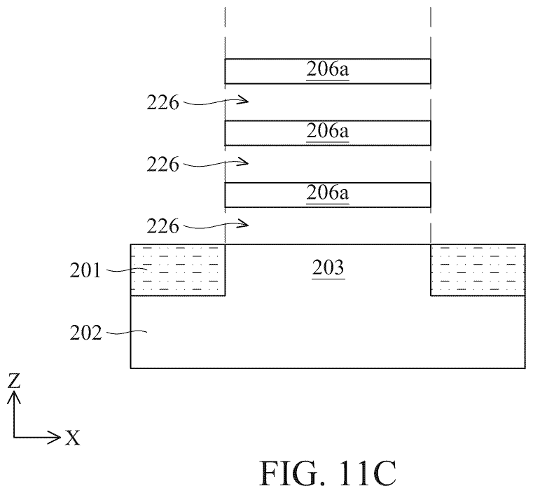

Referring to FIGS. 11A-11C, the dummy gate stack 210 is selectively removed through any suitable lithography and etching processes. In some embodiments, the lithography process includes forming a photoresist layer (resist), exposing the resist to a pattern, performing a post-exposure bake process, and developing the resist to form a masking element, which exposes a region including the dummy gate stack 210. Then, the dummy gate stack 210 is selectively etched through the masking element. In some other embodiments, the gate spacers 212 may be used as the masking element or a part thereof. For example, the dummy gate stack 210 may include polysilicon, the gate spacers 212 and the inner spacers 220 may include dielectric materials, and the channel layers 206a include a semiconductor material. Therefore, an etch selectivity may be achieved by selecting appropriate etching chemicals, such that the dummy gate stack 210 may be removed without substantially affecting the features of the semiconductor structure 200. The removal of the dummy gate stack 210 creates gate trench 228. The gate trench 228 exposes the top surfaces and the side surfaces of the stack of the channel layers 206a and the dielectric layers 216a. In other words, the channel layers 206a and the dielectric layers 216a are exposed at least on two side surfaces in the gate trench 228. Additionally, the gate trench 228 also exposes the top surfaces of the isolation features 201.

Referring to FIGS. 11A-11C, the dielectric layers 216a are also selectively removed through the gate trench 228, for example using wet or dry etching process. The etching chemical is selected such that the dielectric layers 216a have a sufficiently different etching rate as compared to the channel layers 206a, the inner spacers 220, and the gate spacers 212. As a result, the channel layers 206a, the inner spacers 220, and the gate spacers 212 remain substantially unchanged. This selective etching process may include one or more etching steps.

As illustrated in FIGS. 11A-11C, in the present embodiment, the removal of the dielectric layers 216a forms suspended channel layers 206a and openings 226 in between the vertically adjacent layers (e.g. in the Z-direction), thereby exposing the top and bottom surfaces of the channel layers 206a. Each of the channel layers 206a are now exposed circumferentially in the X-Z plane. In addition, the portion of the doped regions of the semiconductor substrate 202 beneath the channel layers 206a are also exposed in the openings 226.

In the examples depicted in FIGS. 11A-11C, the gate trench 228 and the openings 226 vertically adjacent to the gate trench 228 (e.g. in the Z-direction) collectively form an opening having a vertical profile. In other words, the opening collectively formed by the gate trench 228 and its corresponding openings 226 have vertical sidewalls. In some embodiments, such openings having the vertical sidewalls may be formed by a plurality of etch processes. For example, the etch chemistry of the etch process used to remove the dummy gate stack 210 and thereby form the gate trench 228 may include hydrogen bromide (HBr) combined with chlorine (Cl₂), tetrafluoromethane (CF₄), oxygen, or a combination thereof. Furthermore, the etch process used to selectively remove the dielectric layers 216a and thereby form the openings 226 may have an initial etch chemistry including hydrogen bromide (HBr) combined with chlorine (Cl₂), oxygen, or a combination thereof. This initial etch chemistry is followed by a subsequent etch chemistry including hydrogen bromide (HBr) combined with tetrafluoromethane (CF₄), oxygen, or a combination thereof that induces the vertical profile of the opening collectively formed by the gate trench 228 and its corresponding openings 226.

FIG. 11B is an enlarged view of a portion (in the dotted rectangle) of the semiconductor structure 200 in FIG. 11A. In some embodiments, the removal process only removes some, but not all, of the dielectric layers 216a. A portion of the dielectric layers 216a may remain between the inner spacers 220 and the channel layers 206a (or the semiconductor substrate 202, where applicable). Such remaining portion can be referred to as “remaining dielectric layers 216b.”

In some embodiments, the remaining dielectric layers 216b are free of SiGe. In conventional processes, non-channel layers including SiGe are commonly used. After forming epitaxial source/drain features, most of non-channel layers are removed while SiGe residue can remain between adjacent channel layers, causing undesired capacitance between the SiGe residue and adjacent conductive features. In the present disclosure, the semiconductor layers 204 and the intermix layers 205 have been removed, thus SiGe in the ML is negligible (e.g., less than 0.0001% of the total SiGe in the semiconductor layers 204). Therefore, the capacitance between SiGe and other conductive features (e.g., the epitaxial source/drain features 223) is reduced or negligible.

In some embodiments, an etching selectivity of the dielectric layers 216a to the channel layers 206a can be higher than an etching selectivity of the semiconductor layers 204 to the channel layers 206a in conventional processes. In some embodiments, in the removing of the dielectric layers 216a, an etching selectivity of the dielectric layers 216a to the channel layers 206a is greater than 10. If the etching selectivity of the dielectric layers 216a to the channel layers 206a is too small, the channel layers 206a may be etched, thus thicknesses and/or widths of the channel layers 206a may be reduced, which may impact performance of the semiconductor structure 200 (e.g., more SCEs, higher capacitance).

FIG. 11C is a cross-sectional view of the semiconductor structure 200 in FIG. 11A and along the line B-B′ in FIG. 2. In some embodiments, the channel layers 206a has no or little width loss during the removal of the dielectric layers 216a. This can result from the etching selectivity of the dielectric layers 216a to the channel layers 206a, and/or that the channel layers 206a and the adjacent dielectric material 216 have clear boarders that are free of intermix session, as described above. In some embodiments, the channel layers 206a have a width along the X-direction that is equal to or less than a width of a bottom portion of the fin 203 (e.g., a portion of fin 203 contacting the semiconductor substrate 202) along the X-direction by less than 2%. In other words, the width loss of the channel layers 206a in the process is negligible, which improves device performance and reduces capacitance.

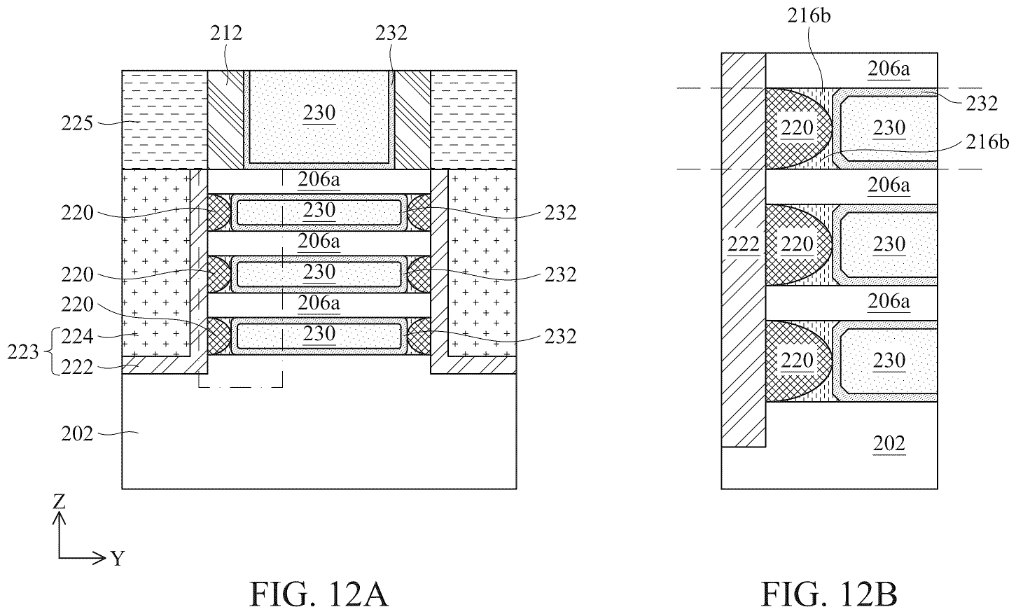

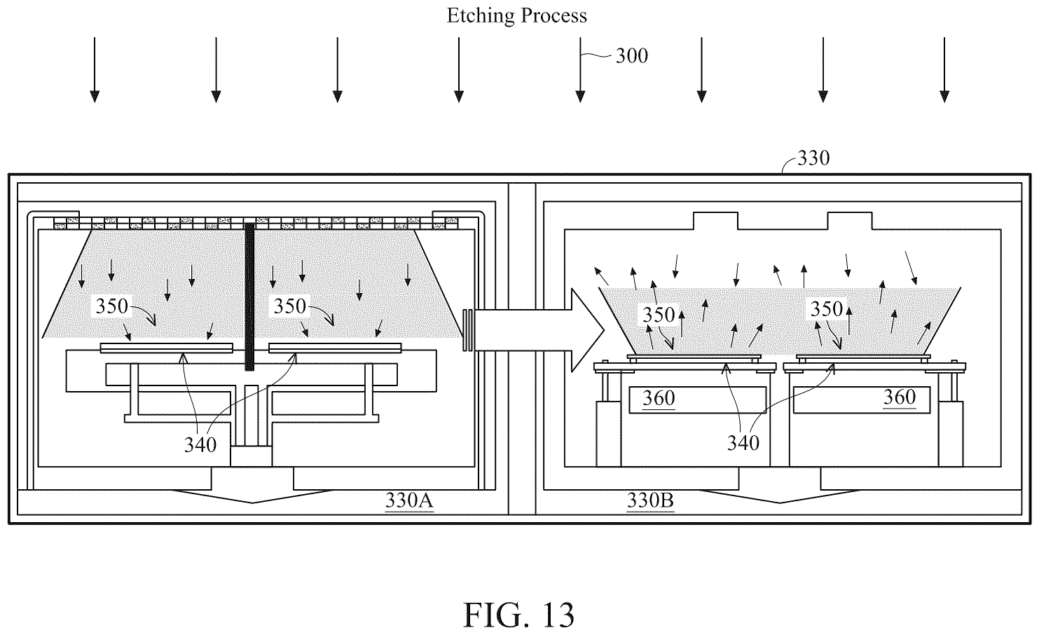

Referring to FIGS. 12A-12B, a metal gate stack is formed. The metal gate stack includes a gate dielectric layer 232 and a gate electrode 230 disposed over the gate dielectric layer 232. For example, the metal gate stack may include a polysilicon gate electrode over a SiON gate dielectric layer. As another example, the metal gate stack may include a metal gate electrode over a high-k dielectric layer. In some instances, a refractory metal layer may interpose between the metal gate electrode (such as an aluminum gate electrode) and the high-k dielectric layer. As yet another example, the metal gate stack may include silicide. The gate dielectric layer 232 is formed between the gate electrode 230 and the channels formed by the channel layers 206a.

In some embodiments, the gate dielectric layer 232 is formed conformally on the semiconductor structure 200. The gate dielectric layer 232 at least partially fills the gate trenches 228. In some embodiments, dielectric interfacial layers may be formed over the channel layers 206a prior to forming the gate dielectric layer 232. Such dielectric interfacial layers improve the adhesion between the channel layers 206a and the gate dielectric layer 232. In the examples depicted in this disclosure, such dielectric interfacial layers are omitted. Instead, in the embodiments shown, the gate dielectric layer 232 is formed around the exposed surfaces of each of the channel layers 206a, such that it wraps around the channel layers 206a in 360 degrees. Additionally, the gate dielectric layer 232 also directly contacts vertical sidewalls of the inner spacers 220, sidewalls of the remaining dielectric layers 216b, and vertical sidewalls of the gate spacers 212. The gate dielectric layer 232 may include a dielectric material having a dielectric constant greater than a dielectric constant of SiO₂, which is approximately 3.9. For example, the gate dielectric layer 232 may include hafnium oxide (HfO₂), which has a dielectric constant in a range from about 18 to about 40. As various other examples, the gate dielectric layer 232 may include ZrO₂, Y₂O₃, La₂O₅, Gd₂O₅, TiO₂, Ta₂O₅, HfErO, HfLaO, HfYO, HfGdO, HfAlO, HfZrO, HfTiO, HfTaO, SrTiO, or combinations thereof. The formation of the gate dielectric layer 232 may be by any suitable processes, such as CVD, PVD, ALD, or combinations thereof.

After forming the gate dielectric layer 232, the gate electrode 230 is formed over the gate dielectric layer 232 to fill the remaining spaces of the gate trenches 228. The gate electrode 230 may include any suitable materials, such as titanium nitride (TiN), tantalum nitride (TaN), titanium aluminide (TiAl), titanium aluminum nitride (TiAlN), tantalum aluminide (TaAl), tantalum aluminum nitride (TaAlN), tantalum aluminum carbide (TaAlC), tantalum carbonitride (TaCN), aluminum (Al), tungsten (W), copper (Cu), cobalt (Co), nickel (Ni), platinum (Pt), or combinations thereof. In some embodiments, a CMP is performed to expose a top surface of the ILD layer 225. The gate dielectric layer 232 and the gate electrode 230 collectively form the metal gate stack, which engages multiple layers within the channel layers 206a (e.g. multiple nanochannels).

FIG. 12B is an enlarged view of a portion (in the dotted rectangle) of the semiconductor structure 200 in FIG. 12A. As previously described in this disclosure, thicknesses along the Z-direction of each channel layers 206a are substantially the same at different locations on an X-Y plane, and the channel layers 206a are substantially unchanged through the process, thus after forming the metal gate stack, thicknesses along the Z-direction of each channel layers 206a remain substantially the same (e.g., less than 5% difference) at different locations on an X-Y plane. If the thicknesses along the Z-direction of each channel layers 206a are not substantially the same (e.g., less than 5% difference) at different locations on an X-Y plane, for example, a thickness on edges (e.g., closer to epitaxial source/drain features) is greater than 10% of a thickness in center (e.g., directly under the metal gate stack above the ML), undesired capacitance may increase. In conventional processes, non-channel layers including SiGe are commonly removed after forming epitaxial source/drain features and before forming the metal gate stack, and the removing of the non-channel layers include multiple etching steps for removal of intermix layers. These multiple etching steps may cause a width reduction of channel layers (e.g., width along x direction) and thicker channel layers on edges (e.g., closer to epitaxial source/drain features) than in center (e.g., directly under the metal gate stack above the ML), thus negatively impacting device performance (e.g., increased SCEs) and increase undesired capacitance. In addition, SiGe in the ML of the present disclosure is negligible (e.g., less than 0.0001% of the total SiGe in the semiconductor layers 204), thus the forming of oxidized Ge during the processes is negligible, which reduces an interface trap effect.

In some embodiments, as depicted in FIG. 12B, in each of the openings 226 between the two adjacent channel layers 206a (or the semiconductor substrate 202, where applicable) (referred to as “top channel layer 206a” and “bottom channel layer 206a”), there are at least one of the remaining dielectric layers 216b (referred as “top remaining dielectric layer 216b” or “bottom remaining dielectric layer 216b”) in direct contact with the top channel layer 206a or the bottom channel layer 206a. The top and/or bottom remaining dielectric layer 216b can have a triangle-like shape in the cross-sectional view as in FIG. 12B. In some embodiments, sidewalls of the top and/or bottom remaining dielectric layer 216b interface with the top and/or bottom channel layer 206a, the adjacent inner spacer 220, and the adjacent gate dielectric layer 232, respectively. In some other embodiments, although not depicted, besides interfacing with these, the top and/or bottom remaining dielectric layer 216b extend to contact with the adjacent epitaxial source/drain feature 223. In such embodiments, the adjacent inner spacer 220 is separated from the top and/or bottom channel layer 206a by the top and/or bottom remaining dielectric layer 216b.

In some embodiments, the top and/or bottom remaining dielectric layer 216b extend between one of the inner spacers 220 (first inner spacer 220) and the gate dielectric layer 232. In some embodiments, the top remaining dielectric layer 216b and the bottom remaining dielectric layer 216b are separated by the first inner spacer 220 and the gate dielectric layer 232 of the metal gate stack. In some other embodiments, the top remaining dielectric layer 216b extends and merges with the bottom remaining dielectric layer 216b. In some embodiments, the top remaining dielectric layer 216b extends to the top channel layer 206a. A top surface of the top remaining dielectric layer 216b and a top surface of the gate dielectric layer 232 can be coplanar, and can be in direct contact with a bottom surface of the top channel layer 206a. Similarly, the bottom remaining dielectric layer 216b extends to the bottom channel layer 206a. A bottom surface of the bottom remaining dielectric layer 216b and a bottom surface of the gate dielectric layers 232 can be coplanar, and can be in direct contact with a top surface of the bottom channel layer 206a.

After forming the gate dielectric layer 232 and the gate electrode 230, a planarization process is performed to remove excess gate materials from the semiconductor structure 200. For example, a CMP process is performed until a top surface of the ILD layer 225 is reached (exposed), such that a top surface of the metal gate stack is substantially planar with the top surface of the ILD layer 225 after the CMP process. Accordingly, the semiconductor structure 200 can include a GAA transistor having a metal gate stack wrapping respective channel layers 206a, such that the metal gate stack is disposed between respective epitaxial source/drain features 223.

Fabrication can proceed to continue fabrication of the semiconductor structure 200. For example, various contacts can be formed to facilitate operation of the GAA transistor. For example, one or more ILD layers, similar to the ILD layer 225, and/or CESL layers can be formed over the semiconductor substrate 202 (in particular, over the ILD layer 225 and the metal gate stack). Contacts can then be formed in the ILD layer 225 and/or ILD layers disposed over the ILD layer 225. For example, a contact is electrically and/or physically coupled with the metal gate stack and another contact is electrically and/or physically coupled to source/drain regions of the GAA transistor (particularly, the epitaxial source/drain features 223). Contacts include a conductive material, such as metal. Metals include aluminum, aluminum alloy (such as aluminum/silicon/copper alloy), copper, copper alloy, titanium, titanium nitride, tantalum, tantalum nitride, tungsten, polysilicon, metal silicide, other suitable metals, or combinations thereof. The metal silicide may include nickel silicide, cobalt silicide, tungsten silicide, tantalum silicide, titanium silicide, platinum silicide, erbium silicide, palladium silicide, or combinations thereof. In some implementations, the ILD layers disposed over the ILD layer 225 and the contacts (for example, extending through the ILD layer 225 and/or the other ILD layers) are a portion of the MLI feature described above.

Other fabrication processes may be applied to the semiconductor structure 200 and may implemented before, during, or after the processes described above, such as various processing steps to form an interconnect structure over the GAA transistors from the frontside of the semiconductor substrate 202 to electrically connects various circuit components. The interconnect structure includes metal lines distributed in multiple metal layers (such as 1^{st} metal layer, 2^{nd} metal layer, 3^{rd} metal layer, and etc. from the bottom up to the top metal layer) to provide horizontal routing and contact features (between the substrate and the first metal layer, and via features (between the metal layers) to provide vertical routing. The semiconductor structure 200 also includes other components, such as other conductive features (such as redistribution layer or RDL), passivation layer(s) to provide sealing effect, and/or bonding structures to provide an interface between the semiconductor structure 200 and a circuit board (such as a printed circuit board) to be formed on the interconnect structure.

Though not intended to be limiting, embodiments of the present disclosure offer benefits for semiconductor processing and semiconductor devices. For example, by removing the non-channel layers including the transition layers before forming the epitaxial source/drain features, SiGe residue becomes negligible before forming the epitaxial source/drain features, thus abnormal doping diffusion and built-in stress (e.g., tensile stress and compressive stress) during following processes are reduced. The early removal of the transition layers also reduces undesired capacitance and device degradation, avoids width loss of channel layers, thus improves performance of the device, reduces short-channel effects (SCEs), and can result in higher current drive and higher logic density.

However, certain improvements can still be made to the semiconductor structure 200 and the fabrication thereof. For example, although the figures discussed above may illustrate the different dielectric materials 216a (see FIG. 7A) and the gate structures (including the metal gate electrode 230 and the gate dielectric 232, see FIG. 12A) in the stack as having equal dimensions in the Y-direction, this is for the sake of simplicity and may not actually represent the profile of the dielectric materials 216a or the gate structure segments in a real-world device. Often times, the fabrication processes performed to form the semiconductor structure 200 may lead to a tapered profile for the dielectric materials 216a and the gate structure segments that eventually replace the dielectric materials 216a.

For example, the topmost one of the dielectric materials 216a and the corresponding topmost gate structure segment may have a shortest lateral dimension in the Y-direction, the bottommost one of the dielectric materials 216a and the corresponding bottommost gate structure segment may have a longest lateral dimension in the Y-direction, and the middle one of the dielectric materials 216a and the corresponding middle gate structure segment may have a lateral dimension between the shortest and the longest in the Y-direction. Such a profile may not allow the devices in which the semiconductor structure 200 is implemented to achieve the optimal performance and/or yield. To address this issue, various aspects of the present disclosure also pertain to an improvement of the etching process used to laterally etch the dielectric materials 216 to form the undercuts 218 (see FIG. 7A). For example, the etching process may include a plurality of etching-baking cycles, where each etching cycle is performed using etching parameters (e.g., etching temperatures and/or pressures and/or baking times) that are specifically configured to tune the profile of the dielectric materials 216a in the stack, as discussed in more detail below.

Referring now to FIG. 13, an etching process 300 is performed as a part of the fabrication of the semiconductor structure 200. In some embodiments, the etching process 300 may be the etching process performed to laterally etch the dielectric materials 216 to form the undercuts 218 (see FIG. 7A). The etching process 300 may include a plurality of etching-baking cycles that are performed using a tool 330 that includes an etching chamber 330A and a baking chamber 330B. The etching step in each cycle is performed in the etching chamber 330A, and the baking step in each cycle is performed in the baking chamber 330B.

In more detail, one or more wafers 340 on which the semiconductor structure 200 is formed is placed in the etching chamber 330A following the fabrication steps discussed above with reference to FIGS. 6A-6B, but prior to the fabrication steps discussed above with reference to FIGS. 7A-7B. As such, the wafer 340 includes the dielectric materials 216 that are formed in a vertical stack, interleaving with the semiconductor layers 206 in the Z-direction. In some embodiments, the dielectric materials 216 include silicon dioxide (SiO₂), which can be etched away using an etchant that includes hydrofluoric acid (HF) and/or ammonia (NH₃). As such, the etching step is executed at least in part by applying HF and/or NH₃ as etchants in the etching chamber 330A. According to the various aspects of the present disclosure, the etching step is performed with a relatively low temperature and a relatively high pressure. In some embodiments, the temperature at which the etching step is performed is in a range between about 16 degrees Celsius and about 20 degrees Celsius, for example, at around 18 degrees Celsius. In some embodiments, the pressure at which the etching step is performed is in a range between about 600 milli-Torrs and about 800 milli-Torrs, for example, at around 700 milli-Torrs. These process parameters are not randomly chosen but specifically configured to optimize the lateral etching profile of the dielectric materials 216, as will be discussed in more detail below.

The dielectric material 260 (e.g., SiO₂) reacts with the etchants (e.g., HF and/or NH₃) to form a byproduct 350 on the surface of the wafer 340. In some embodiments, the byproduct 350 includes ammonium fluorosilicate ((NH₄)₂SiF_{6(S)}). The byproduct 350 is then removed in the baking step of the etching process 300. For example, in each of the cycles of the etching process 300, after the etching step is completed, the one or more wafers 340 may be sent to the baking chamber 330B of the tool 330. The baking chamber includes one or more heaters 360 over which the wafers 340 are placed. The one or more heaters 360 generate heat, and the amount of heat generated by the heaters 360 can be controlled to configure the temperature inside the baking chamber 330B.

In some embodiments, the baking step is performed at a baking temperature in a range between about 120 degrees Celsius and about 130 degrees Celsius, for example, at around 125 degrees Celsius. The baking step is also performed for a baking duration in a range between about 18 seconds and about 22 seconds, for example, at around 20 seconds. It is understood that the above baking duration is specially configured to adjust the amount of byproduct remaining on the dielectric layers 216a in the stack (e.g., the top or middle ones of the dielectric layers 216a), which will help affect an etching of these dielectric layers 216a, as will be discussed in greater detail below. The baking step transforms the byproduct 350 into a gaseous product, which can then be removed from the baking chamber 330B. At the end of each baking step, the one or more wafers 340 may be sent back to the etching chamber 330A for the subsequent etching step of the etching process 300 to be performed.

The etching process 300 may include many cycles of etching and baking, until a desired profile for the lateral recesses (e.g., the undercuts 218) is achieved. In more detail, the stack dielectric layers 216a (see FIG. 7A) formed as a result of the etching process 300 may have tunable lateral dimensions in the Y-direction. In some embodiments, the lateral dimensions of the dielectric layers 216a in the Y-direction are tuned such that they are substantially uniform with one another. For example, in some embodiments, a ratio between a lateral dimension of a shortest one of the dielectric layers and a lateral dimension of a longest one of the dielectric layers is within a range between about 0.91:1 and about 1:1 in the cross-sectional side view, and a variation among the various lateral dimensions of the dielectric layers 216a is less than 1.4 nanometers.

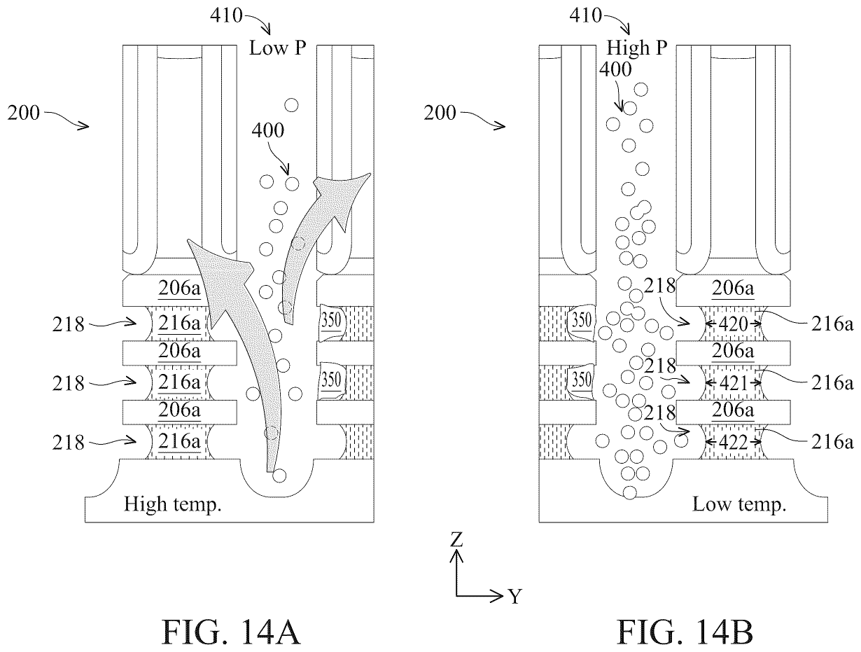

The ability to configure the etching profiles of the dielectric layers 216a is at least partially attributed to the specific etching process parameters of the present disclosure. For example, referring to FIGS. 14A and 14B, diagrammatic fragmentary cross-sectional views of a portion of the semiconductor structure 200 are illustrated. In FIG. 14A, an etching process is performed to the semiconductor structure 200 with a relatively low pressure and a relatively high temperature. Under these process conditions, the etchant (represented by etchant particles 400) may not penetrate sufficiently deep into the opening 410. In other words, the etchant particles 400 may be distributed more at or near the topmost one of the dielectric layers 216a than at the bottommost one of the dielectric layers 216a. Consequently, the topmost one of the dielectric layers 216a may experience more etching than the bottommost one of the dielectric layers 216a, which may result in an etching profile for the semiconductor structure 200 where the topmost dielectric layer 216a has the smallest lateral dimension in the Y-direction, and the bottommost dielectric layer 216a has the greatest lateral dimension. If the difference between these lateral dimensions becomes too big, then device performance and/or yield may suffer.

In comparison, at a relatively low temperature (e.g., between 16 degrees Celsius and about 20 degrees Celsius) and/or a relatively high process pressure (e.g., between about 600 milli-Torrs and about 800 milli-Torrs), the etchant particles 400 may be distributed more evenly in the opening 410, even at the bottom of the opening 410. Furthermore, due to these process conditions, the etchant particles 400 may also be able to remain at the bottom of the opening 410 for a longer period of time and react more easily with the etchant. Consequently, all of the dielectric layers 216a in the stack may experience a more even amount of etching, which may result in an etching profile for the semiconductor structure 200 where the topmost dielectric layer 216a, the middle dielectric layer 216a, and the bottommost dielectric layer 216a having lateral dimensions that are more uniform with one another.

For example, as shown in FIG. 14B, topmost dielectric layer 216a, the middle dielectric layer 216a, and the bottommost dielectric layer 216a have lateral dimensions 420, 421, and 422, respectively. The lateral dimensions 420-422 are measured across the narrowest portion of the respective dielectric layers 216a in the Y-direction (since the undercut 218 may not have a completely vertical sidewall). In other words, the lateral dimensions 420-422 may be considered the minimum lateral dimensions of the respective dielectric layers 216a in the Y-direction. To illustrate the uniformity, suppose that the lateral dimension 421 is the shortest, and the lateral dimension 422 is the longest, and the lateral dimension 420 is in between the lateral dimensions 421 and 422. In such an embodiment, a ratio between the lateral dimension 421 and the lateral dimension 422 is within a range between about 0.91:1 and about 1:1, and a difference between the lateral dimensions 421 and 422 (in absolute value) is less than 1.4 nanometers.

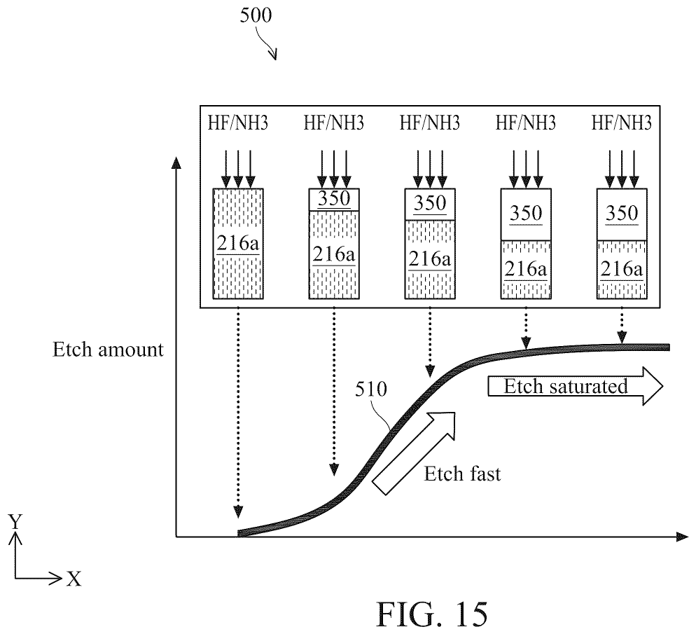

The greater degree of uniformity among the lateral dimensions 420-422 is also partially attributed to the byproduct 350 (see the discussions above with reference to FIG. 13) serving as an etching stop layer herein. In more detail, referring to FIG. 15, a graph 500 is illustrated, which helps to demonstrate aspects of the etching process 300 discussed above that take into account the effects of the byproduct 350. The graph 500 includes a horizontal axis (represented by an X-axis in FIG. 15) and a vertical axis (represented by a Y-axis in FIG. 15). Note that the X-axis and the Y-axis in FIG. 15 are meant to represent the two dimensions of the graph 500 and therefore are not to be confused with the X-axis and the Y-axis in the preceding figures. In any case, the X-axis in FIG. 15 may represent time, for example, how much time has elapsed during an etching step in each etching-baking cycle of the etching process 300. The Y-axis in FIG. 15 may represent an etching amount, for example, an amount of the dielectric layer 216 that is etched in the etching step. As such, a curve 510 in FIG. 15 represents how much the dielectric layer 216a has been etched over time.

As is shown in FIG. 15, at the early stages of the etching step, the dielectric layer 216a is etched relatively fast, since there is nothing blocking the dielectric layer 216a from being etched. As time goes on, the byproduct 350 starts being formed due to the chemical reaction between the etchant HF/NH₃ and the material of the dielectric layer 216a (e.g., SiO₂). As the byproduct 350 accumulates on the dielectric layer 216a (e.g., on a sidewall of the dielectric layer 216a in FIG. 14B), it begins to interfere with the chemical reaction between the etchant and the dielectric layer 216a. As a result, the etching of the dielectric layer 216a may begin to slow down. At the late stages of the etching step, there may be a substantial amount of the byproduct 350 formed on the sidewall of the dielectric layer 216a, which may lead to a saturation of the etching, meaning very little (if any) of the dielectric layer 216a is etched at that time. In this manner, the byproduct 350 may function similar to an etching-stop layer, in that it at least blocks or otherwise reduces the etching of the dielectric later 216a once the byproduct 350 reaches a sufficient thickness.

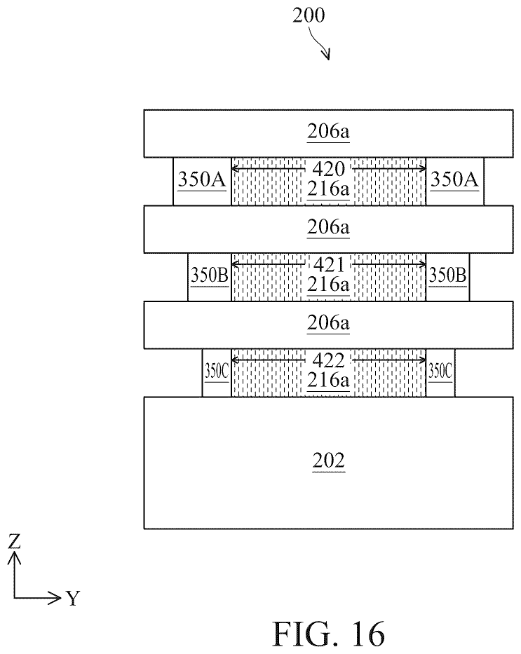

The etch-blocking properties of the byproduct 350 also allows for flexible tuning of the profile of the resulting stack of dielectric layers 216a. For example, referring now to FIG. 16, a diagrammatic fragmentary cross-sectional view of a portion of the semiconductor structure 200 is illustrated. The illustrated portion of the semiconductor structure 200 includes an example stack of dielectric layers 216a interleaving with the semiconductor layers 206a in the Z-direction. According to the various aspects of the present disclosure, certain process parameters may be tuned to configure the formation of the byproduct 350 (e.g., with respect to its formation location and/or thickness in the Y-direction). For example, at lower etching temperatures and/or higher etching pressures (e.g., for the etching step of the etching process 300 discussed above), the byproduct 350 is more easily formed at the top of the stack, and not as much at the bottom of the stack.

In the embodiment illustrated in FIG. 16, the byproduct 350A (formed on side surfaces of the topmost dielectric layer 216a) has a greatest thickness in the Y-direction, the byproduct 350B (formed on side surfaces of the middle dielectric layer 216a) has an intermediate thickness in the Y-direction, and the byproduct 350C (formed on side surfaces of the bottommost dielectric layer 216a) has a smallest thickness in the Y-direction. Due to the differences in thicknesses of the byproducts 350A-350C, the byproduct 350A may have a most significant etch-blocking effect, the byproduct 350B may have an intermediate etch-blocking effect, and the byproduct 350C may have the least significant etch-blocking effect. As discussed above, during the etching step of the etching process 300, the general trend is that the etching of the dielectric layer 216 is more significant at the top of the stack but not as significant at the bottom of the stack, even with the etching process parameters tuned to cause the etchant particles to penetrate more deeply to reach the dielectric layers 216a located at the bottom of the stack. Here, the fact that the byproducts 350A-350C may help block the etching of the top dielectric layers 216a more than the etching of the bottom dielectric layers 216a may help to compensate for the general trend of the top dielectric layers 216a being etched more than the bottom dielectric layers 216a. As a result, the resulting dielectric layers 216a may have more uniform lateral dimensions. For example, in an embodiment where the etching temperature is in a range between about 16 degrees Celsius and about 20 degrees Celsius, and the etching pressure is in a range between about 600 milli-Torrs and about 800 milli-Torrs, a ratio between a shortest one of the lateral dimensions 420-422 and a longest one of the lateral dimensions 420-422 is within a range between about 0.91:1 and about 1:1 in the cross-sectional side view, and a variation among the shortest one and the longest one of the lateral dimensions 420-422 is less than 1.4 nanometers, for the resulting semiconductor structure 200.

Note that the amount of time for baking in the baking step of each cycle of the etching process 300 may also be configured to adjust the profile of the dielectric layers 216a. This is because the byproduct 350 is removed via the baking, and the amount of baking time may affect the removal of the byproduct 350, which in turn may affect the etching of the dielectric layers 216a. In the embodiments where the baking time is between about 18 seconds and about 22 seconds, such a baking time duration helps to promote the uniformity of the lateral dimensions of the resulting dielectric layers 216a. Furthermore, such a baking time duration is relatively short, which helps to avoid inadvertent damage to the epi-layers (e.g., the source/drain features).

It is understood that FIG. 16 is merely illustrated to provide an example to facilitate the above discussions, and it may not represent the actual semiconductor structure 200 in accurate scale. For example, in some embodiments, the etching process parameters (e.g., temperature and/or pressure) may be tuned such that very little, if any, byproduct 350C is formed on the side surfaces of the bottommost dielectric layer 216a, which will allow the bottommost dielectric layer to be etched even more. In that embodiment, the bottommost dielectric layer 216a may have the smallest lateral dimension 422 out of the three lateral dimensions 420-422. In some other embodiments, the formation of the byproducts 350A-350C may also be configured such that the middle one of the dielectric layer 216a may have the shortest lateral dimension 421 out of the three lateral dimensions 420-422. The ability to achieve varying profiles of the dielectric layers 216a in the stack may allow for more design and/or manufacturing flexibility.

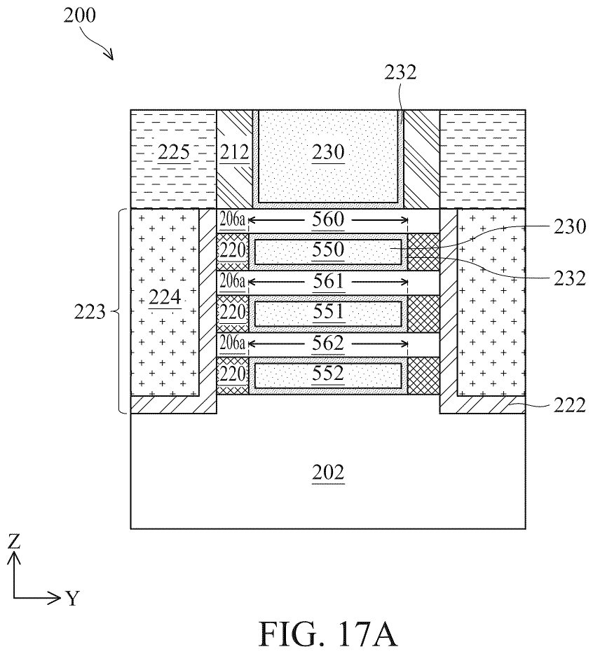

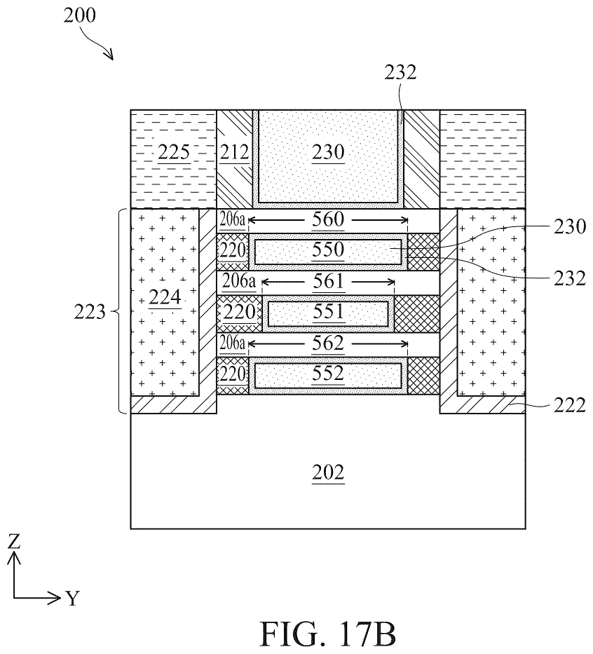

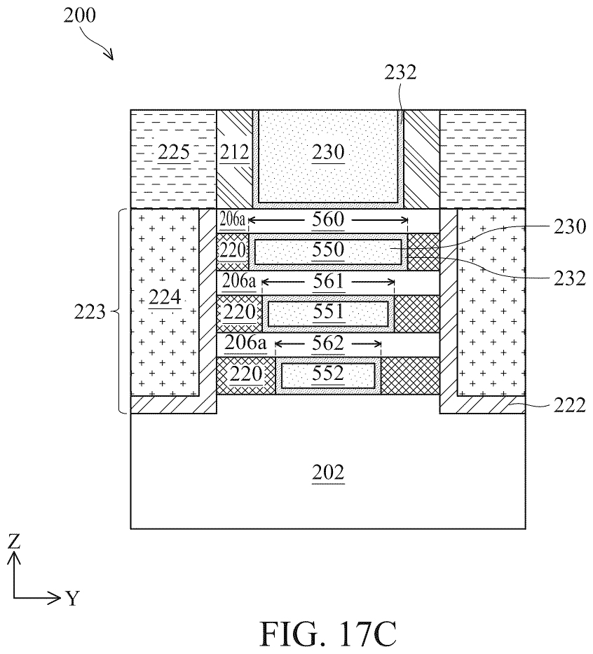

As discussed above with reference to FIG. 12A, eventually the dielectric layers 216a will be replaced by gate structures that include the gate electrode 230 and the gate dielectric 232. Thus, the gate structure of the semiconductor structure 200 may at least partially assume the profiles and/or dimensions of the dielectric layers 216a. Since the profiles of the dielectric layers 216 can be flexibly configured, that means the profiles of the corresponding gate structures can be flexibly configured as well. For example, referring now to FIGS. 17A-17C, the diagrammatic fragmentary cross-sectional views of a portion of the semiconductor structure 200 according to various embodiments are illustrated. The illustrated portion of the semiconductor structure 200 includes the semiconductor substrate 202, source/drain features 223, inner spacers 220, ILD 225, gate electrode 230, gate dielectric 232, gate spacers 212, etc., as discussed above with reference to FIG. 1A. The illustrated portion of the semiconductor structure 200 also includes the stack of semiconductor layers 206a interleaving with gate structures 550-552 in the Z-direction. The gate structures 550-552 may each include a corresponding gate dielectric 232 and a corresponding gate electrode 230. In the different embodiments shown in FIGS. 17A-17C, the gate structures 550-552 may have different lateral dimensions.

For example, the gate structures 550-552 have lateral dimensions 560-562, respectively. In the embodiment of FIG. 17A, the process parameters of the etching process 300 discussed above may be configured (e.g., by adjusting the process temperature and/or pressure of the etching step and/or by adjusting the baking time of the baking step of each cycle) such that the lateral dimensions 560-562 may be substantially uniform with one another. Meanwhile, in the embodiment of FIG. 17B, the process parameters of the etching process 300 discussed above may be configured such that the lateral dimensions 561 is smaller than the lateral dimension 560 and/or the lateral dimension 562. In the embodiment of FIG. 17C, the process parameters of the etching process 300 discussed above may be configured such that the lateral dimensions 562 is smaller than the lateral dimension 561, which is smaller than the lateral dimension 560. Other suitable profiles of the gate structures may also be envisioned, but they are not specifically illustrated herein for reasons of simplicity. As discussed above, each of the gate structure profiles shown in FIGS. 17A-17C may be useful or beneficial for a specific type of IC application. As such, the present disclosure offers design and/or manufacturing versatility.

Note that due to the varying lateral dimensions 560-562 of the gate structures 550-552, their respective neighboring inner spacers 220 may also have varying lateral dimensions in the Y-direction. This is because the overall dimension for each set of inner spacers 220 and its corresponding gate structure 560-562 is defined by the distance between the two source/drain features 223 located on opposite sides, which does not change substantially. Therefore, a longer gate structure is generally compensated for by a shorter inner spacer, or vice versa.

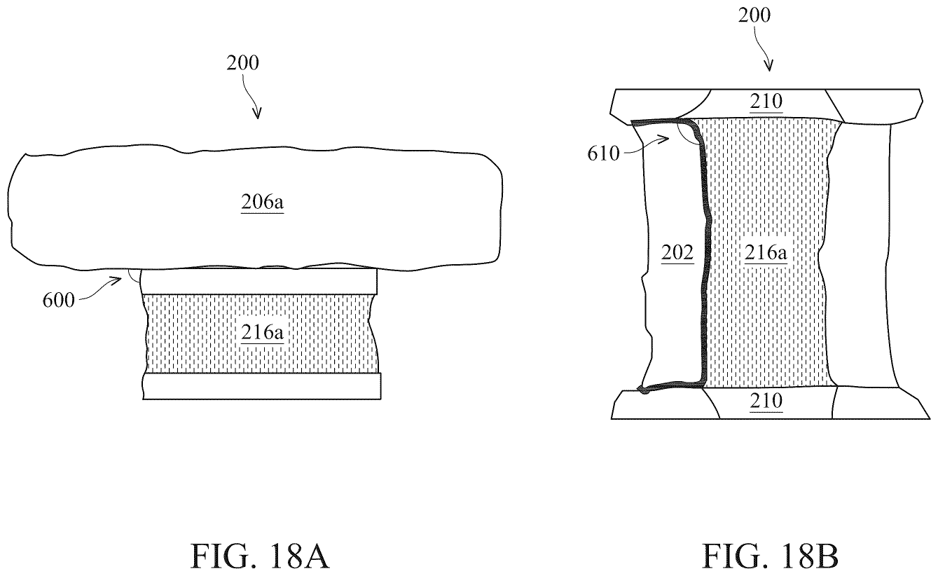

FIGS. 18A and 18B illustrate various angles that are formed by the semiconductor structure 200 of the present disclosure during fabrication. In more detail, FIG. 18A is a crude cross-sectional view of a portion of the semiconductor structure 200 that includes one of the dielectric layers 216a (which may include a low temperature oxide (LTOX) component and a component formed by flowable chemical vapor deposition (FCVD)) and one of the semiconductor layers 206a. In the cross-sectional view of FIG. 18A, the semiconductor layer 206a and the dielectric layer 216a may define an angle 600. In some embodiments, the angle 600 is in a range between about 105 degrees and about 115 degrees, for example, at around 110 degrees. Such a value of the angle 600 is substantially less than semiconductor structures formed by other techniques. For example, the angle 600 is more similar to a right angle, whereas a corresponding angle for semiconductor structures formed by other techniques may resemble more of a curve or an arc and may exceed 120 degrees.

Meanwhile, FIG. 18B is a planar top view of a portion of the semiconductor structure 200 that includes one of the dielectric layers 216a, a neighboring portion of the semiconductor layer 202, and a neighboring portion of the dummy gate stack 210 that includes polysilicon. In the planar top view of FIG. 18B, the semiconductor layer 202 and the dielectric layer 216a may define an angle 610. In some embodiments, the angle 610 is in a range between about 90 degrees and about 100 degrees, for example, at around 95 degrees. Such a value of the angle 610 is substantially less than semiconductor structures formed by other techniques. For example, the angle 610 is more similar to a right angle, whereas a corresponding angle for semiconductor structures formed by other techniques may resemble more of a curve or an arc and may exceeds 115 degrees. The sharper angles 600 and 610 may be unique physical characteristics of the semiconductor structure 200 formed using the fabrication methods of the present disclosure.

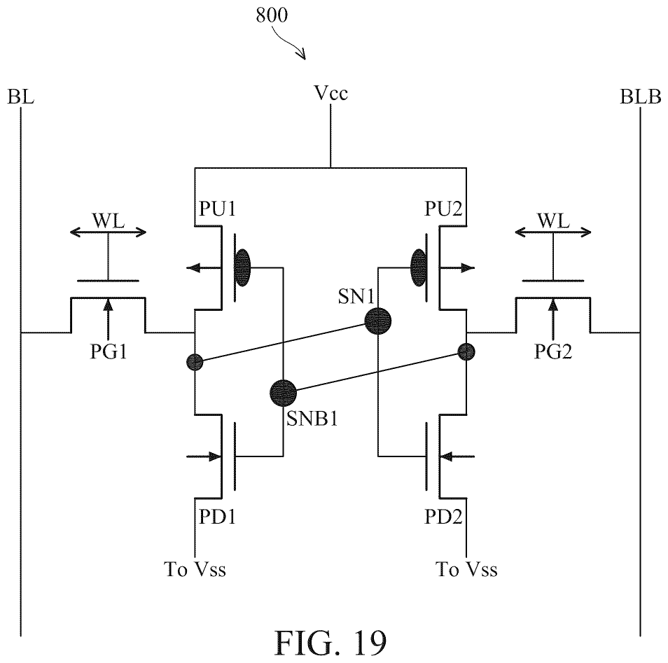

FIG. 19 illustrates an example type of memory device in which the semiconductor structure 200 may be implemented. In that regard, FIG. 19 illustrates the circuit schematic of an example Static Random-Access Memory (SRAM) device, for example, as a single-port SRAM cell (e.g., 1-bit SRAM cell) 800. The single-port SRAM cell 800 includes pull-up transistors PU1, PU2; pull-down transistors PD1, PD2; and pass-gate transistors PG1, PG2. As show in the circuit diagram, transistors PU1 and PU2 are p-type transistors, and transistors PG1, PG2, PD1, and PD2 are n-type transistors. According to the various aspects of the present disclosure, the PG1, PG2, PD1, and PD2 transistors are implemented with thinner spacers than the PU1 and PU2 transistors. Since the SRAM cell 800 includes six transistors in the illustrated embodiment, it may also be referred to as a 6T SRAM cell. Regardless, the transistor 710A may be used to implement the PG1, PG2, PD1, PD2, PU1, and/or the PU2 transistors.

The drains of pull-up transistor PU1 and pull-down transistor PD1 are coupled together, and the drains of pull-up transistor PU2 and pull-down transistor PD2 are coupled together. Transistors PU1 and PD1 are cross-coupled with transistors PU2 and PD2 to form a first data latch. The gates of transistors PU2 and PD2 are coupled together and to the drains of transistors PU1 and PD1 to form a first storage node SN1, and the gates of transistors PU1 and PD1 are coupled together and to the drains of transistors PU2 and PD2 to form a complementary first storage node SNB1. Sources of the pull-up transistors PU1 and PU2 are coupled to power voltage Vcc (also referred to as Vdd), and the sources of the pull-down transistors PD1 and PD2 are coupled to a voltage Vss, which may be an electrical ground in some embodiments.

The first storage node SN1 of the first data latch is coupled to bit line BL through pass-gate transistor PG1, and the complementary first storage node SNB1 is coupled to complementary bit line BLB through pass-gate transistor PG2. The first storage node SN1 and the complementary first storage node SNB1 are complementary nodes that are often at opposite logic levels (logic high or logic low). Gates of pass-gate transistors PG1 and PG2 are coupled to a word line WL. SRAM devices such as the SRAM cell 800 may be implemented using “planar” transistor devices, with FinFET devices, and/or with GAA devices.

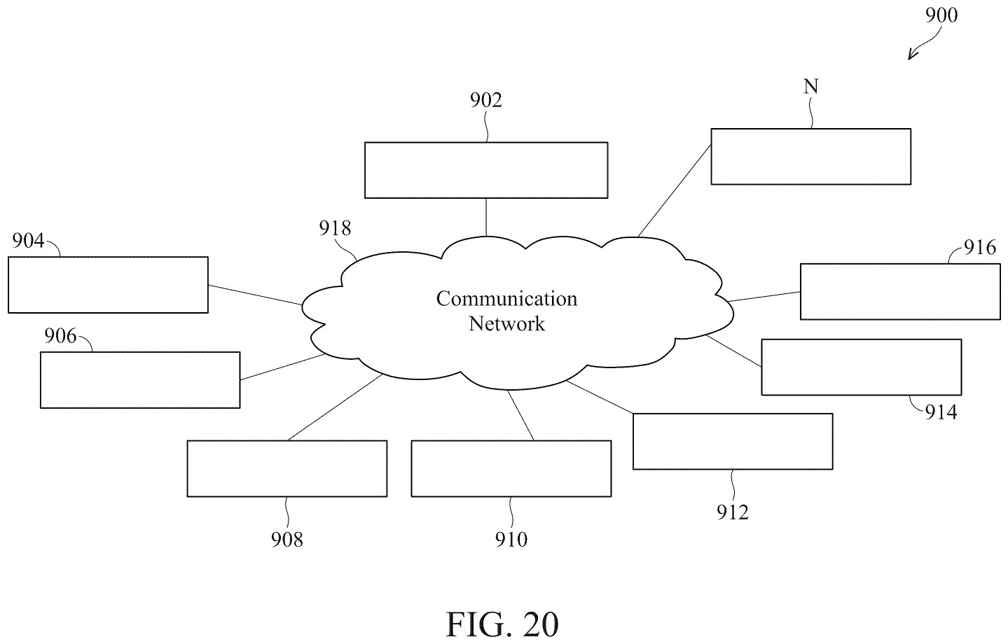

FIG. 20 illustrates an integrated circuit fabrication system 900 that can be used to fabricate the semiconductor structure 200 according to embodiments of the present disclosure. The fabrication system 900 includes a plurality of entities 902, 904, 906, 908, 910, 912, 914, 916 . . . , N that are connected by a communications network 918. The network 918 may be a single network or may be a variety of different networks, such as an intranet and the Internet, and may include both wire line and wireless communication channels.

In an embodiment, the entity 902 represents a service system for manufacturing collaboration; the entity 904 represents an user, such as product engineer monitoring the interested products; the entity 906 represents an engineer, such as a processing engineer to control process and the relevant recipes, or an equipment engineer to monitor or tune the conditions and setting of the processing tools; the entity 908 represents a metrology tool for IC testing and measurement; the entity 910 represents a semiconductor processing tool, such an EUV tool that is used to perform lithography processes to define the gate spacers of an SRAM device; the entity 912 represents a virtual metrology module associated with the processing tool 910; the entity 914 represents an advanced processing control module associated with the processing tool 910 and additionally other processing tools; and the entity 916 represents a sampling module associated with the processing tool 910.

Each entity may interact with other entities and may provide integrated circuit fabrication, processing control, and/or calculating capability to and/or receive such capabilities from the other entities. Each entity may also include one or more computer systems for performing calculations and carrying out automations. For example, the advanced processing control module of the entity 914 may include a plurality of computer hardware having software instructions encoded therein. The computer hardware may include hard drives, flash drives, CD-ROMs, RAM memory, display devices (e.g., monitors), input/output device (e.g., mouse and keyboard). The software instructions may be written in any suitable programming language and may be designed to carry out specific tasks.

The integrated circuit fabrication system 900 enables interaction among the entities for the purpose of integrated circuit (IC) manufacturing, as well as the advanced processing control of the IC manufacturing. In an embodiment, the advanced processing control includes adjusting the processing conditions, settings, and/or recipes of one processing tool applicable to the relevant wafers according to the metrology results.

In another embodiment, the metrology results are measured from a subset of processed wafers according to an optimal sampling rate determined based on the process quality and/or product quality. In yet another embodiment, the metrology results are measured from chosen fields and points of the subset of processed wafers according to an optimal sampling field/point determined based on various characteristics of the process quality and/or product quality.

One of the capabilities provided by the IC fabrication system 900 may enable collaboration and information access in such areas as design, engineering, and processing, metrology, and advanced processing control. Another capability provided by the IC fabrication system 900 may integrate systems between facilities, such as between the metrology tool and the processing tool. Such integration enables facilities to coordinate their activities. For example, integrating the metrology tool and the processing tool may enable manufacturing information to be incorporated more efficiently into the fabrication process or the APC module, and may enable wafer data from the online or in site measurement with the metrology tool integrated in the associated processing tool.

In summary, the present disclosure uses unique fabrication processes to form semiconductor structures as part of GAA devices. For example, the present disclosure performs a lateral etching process to a dielectric layer (in a vertical stack, interleaving with semiconductor layers) in a GAA device, where the lateral etching process includes a plurality of etching-baking cycles. Each etching cycle is performed with a relatively low temperature and a relatively high pressure. The etching cycle generates a byproduct, which can then be removed via the baking cycle. For example, the baking cycle applies heat to the GAA device to transform the byproduct into a gaseous product that can be removed. The etched dielectric layer is eventually replaced by a high-k metal gate structure. The present disclosure offers various advantages. However, it is understood that not all advantages are discussed herein, different embodiments may offer different advantages, and that no particular advantage is required for any embodiment. One advantage is improved device performance. For example, if the lateral etching of the dielectric layers is not configured carefully, the dielectric layers in the stack may have quite uneven lateral dimensions. This is because the lateral etching process typically etches the upper dielectric layers in the stack more than the lower dielectric layers in the stack. The lack of uniformity may be inherited by the gate structures that will be formed to replace the dielectric layers, which will degrade device performance. Here, the etching process parameters (e.g., low temperature and high pressure) are specifically configured to enhance the etching of the lower dielectric layers in the stack, which will improve the uniformity of the lateral dimensions of the etched dielectric layers. In addition, the etching generates a byproduct, which may be tuned by the process parameters to form more on the side surfaces of the upper dielectric layers in the stack. The byproduct may block or otherwise slow down the etching of the dielectric layer on which it is formed. As such, the etching of the upper dielectric layers may be further slowed by the presence of the byproduct. As a result, the dielectric layers after the etching may have relatively uniform lateral dimensions, which translates into relatively uniform lateral dimensions of the gate structures eventually. Consequently, device performance is improved. Other advantages may include compatibility with existing fabrication processes (including for both FinFET and GAA processes) and the case and low cost of implementation.

One aspect of the present disclosure pertains to a method. According to the method, a stack of first semiconductor layers and second semiconductor layers is formed. The first semiconductor layers each have a first material composition. The second semiconductor layers each have a second material composition different from the first material composition. The first semiconductor layers interleave with the second semiconductor layers in the stack. The second semiconductor layers are replaced with a plurality of dielectric layers. An etching process is performed to the dielectric layers. The etching is performed at a process pressure between about 600 milli-Torrs and about 800 milli-Torrs or at a process temperature between about 16 degrees Celsius and about 20 degrees Celsius.

Another aspect of the present disclosure pertains to a method. According to the method, a stack of first semiconductor layers and second semiconductor layers is formed. The first semiconductor layers each have a first material composition. The second semiconductor layers each have a second material composition different from the first material composition. The first semiconductor layers interleave with the second semiconductor layers in the stack. The second semiconductor layers are replaced with a plurality of dielectric layers. The dielectric layers are etched laterally, such that the dielectric layers each have smaller lateral dimensions than the first semiconductor layers in a cross-sectional side view. The etching is performed such that a ratio between a lateral dimension of a shortest one of the dielectric layers and a lateral dimension of a longest one of the dielectric layers is within a range between about 0.91:1 and about 1:1 in the cross-sectional side view

Another aspect of the present disclosure pertains to a device. The device includes a stack of semiconductor layers disposed over a substrate. The device includes a gate structure wrapping around each of the stack of semiconductor layers. In a cross-sectional side view: the gate structure includes at least a first portion, a second portion disposed over the first portion, and a third portion disposed over the second portion; the first portion, the second portion, and the third portion have a first lateral dimension, a second lateral dimension, and a third lateral dimension, respectively; and a variation among the first lateral dimension, the second lateral dimension, and the third lateral dimension is less than 1.4 nanometers.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, comprising:
forming a stack of first semiconductor layers and second semiconductor layers, wherein the first semiconductor layers each have a first material composition, wherein the second semiconductor layers each have a second material composition different from the first material composition, and wherein the first semiconductor layers interleave with the second semiconductor layers in the stack;
replacing the second semiconductor layers with a plurality of dielectric layers; and
performing an etching process to the dielectric layers, wherein the etching is performed at a process pressure between about 600 milli-Torrs and about 800 milli-Torrs or at a process temperature between about 16 degrees Celsius and about 20 degrees Celsius.

2. The method of claim 1, wherein:
the etching process is performed through a plurality of cycles; and
each of the cycles comprises an etching step performed at an etching chamber and a baking step performed at a baking chamber.

3. The method of claim 2, wherein the baking step is performed at a baking temperature in a range between about 120 degrees Celsius and about 130 degrees Celsius.

4. The method of claim 2, wherein:
the etching step generates a byproduct from the dielectric layers; and
the baking step transforms the byproduct into a gaseous chemical that is removable from the baking chamber.

5. The method of claim 4, wherein:
the etching step is performed at least in part using an etchant that contains HF or NH₃; and
the byproduct contains (NH₄)₂SiF6(s).

6. The method of claim 1, wherein the etching process laterally etches the dielectric layers without substantially etching the first semiconductor layers.

7. A method of forming a semiconductor device, comprising:
forming a stack of first semiconductor layers and second semiconductor layers, wherein the first semiconductor layers each have a first material composition, wherein the second semiconductor layers each have a second material composition different from the first material composition, and wherein the first semiconductor layers interleave with the second semiconductor layers in the stack;
replacing the second semiconductor layers with a plurality of dielectric layers; and
etching the dielectric layers laterally, such that the dielectric layers each have smaller lateral dimensions than the first semiconductor layers in a cross-sectional side view, and wherein the etching is performed such that a ratio between a lateral dimension of a shortest one of the dielectric layers and a lateral dimension of a longest one of the dielectric layers is within a range between about 0.91:1 and about 1:1 in the cross-sectional side view.

8. The method of claim 7, wherein the etching is performed using an etchant that contains HF or NH₃.

9. The method of claim 7, wherein the etching generates a byproduct that contains (NH₄)₂SiF6(s).

10. The method of claim 9, wherein the byproduct is removable by applying heat.

11. The method of claim 7, wherein the etching is performed at a process pressure between about 600 milli-Torrs and about 800 milli-Torrs.

12. The method of claim 7, wherein the etching is performed at a process temperature between about 16 degrees Celsius and about 20 degrees Celsius.

13. The method of claim 7, wherein the replacing the second semiconductor layer comprises:
etching away the second semiconductor layer with an etching process that has an etching selectivity between the first semiconductor material composition and the second semiconductor material composition; and
forming the dielectric layer in place of the etched away second semiconductor layer.

14. The method of claim 13, wherein the dielectric layer is formed to contain silicon oxide.

15. The method of claim 7, wherein the etching comprises a plurality of cycles, and wherein each cycle includes an etching step and a thermal baking step.

16. The method of claim 15, wherein the thermal baking step of each cycle is performed at a baking temperature in a range between about 120 degrees Celsius and about 130 degrees Celsius.

17. A semiconductor device, comprising:
a stack of semiconductor layers disposed over a substrate; and
a gate structure wrapping around each of the stack of semiconductor layers;
wherein in a cross-sectional side view:
the gate structure includes at least a first portion, a second portion disposed over the first portion, and a third portion disposed over the second portion;
the first portion, the second portion, and the third portion have a first lateral dimension, a second lateral dimension, and a third lateral dimension, respectively; and
a variation among the first lateral dimension, the second lateral dimension, and the third lateral dimension is less than 1.4 nanometers.

18. The device of claim 17, wherein:
the first lateral dimension is smaller than the second lateral dimension or the third lateral dimension; or
the second lateral dimension is smaller than the first lateral dimension or the third lateral dimension.

19. The device of claim 17, wherein a ratio between a longest one of the first, second, and third lateral dimensions and a longest one of the first, second, and third lateral dimensions is within a range between about 0.91:1 and about 1:1 in the cross-sectional side view.

20. The device of claim 17, further comprising:
a first inner spacer disposed on a side surface of the first portion of the gate structure;
a second inner spacer disposed on a side surface of the second portion of the gate structure; and
a third inner spacer disposed on a side surface of the third portion of the gate structure;
wherein the first inner spacer, the second inner spacer, and the third inner spacer have varying lateral dimensions.
